(19) United States
(12) Patent Application Publication
(10) Pub. No.: US 2026/0223731 A1
(43) Pub. Date: Jul. 30, 2026

(54) ASSEMBLY STRUCTURE AND ELECTRONIC DEVICE AND MANUFACTURING METHOD FOR MANUFACTURING THE SAME

(71) Applicant: Advanced Semiconductor Engineering, Inc., Kaohsiung (TW)

(72) Inventors: Chih-Jing HSU, Kaohsiung (TW); Yu-Yuan YEH, Kaohsiung (TW); Zhao-Ze JIANG, Kaohsiung (TW); Hsu-Nan FANG, Kaohsiung (TW); Chen-Hung LEE, Kaohsiung (TW); Che-Ming HSU, Kaohsiung (TW); Min-Tzu HSU, Kaohsiung (TW)

(73) Assignee: Advanced Semiconductor Engineering, Inc., Kaohsiung (TW)

(21) Appl. No.: 19/449,404

(22) Filed: Jan. 14, 2026

Related U.S. Application Data
(60) Provisional application No. 63/749,463, filed on Jan. 24, 2025.

(51) Int. Cl. H10W 80/00; H10W 90/00

(52) U.S. Cl. CPC H10W 80/327; H10W 90/792

(57) ABSTRACT

An assembly structure and an electronic device and a manufacturing method for manufacturing the same are provided. The manufacturing method includes: forming a first dielectric layer and a first connector on a first main portion of a first electronic device, wherein the first dielectric layer includes an organic polymer material, the first dielectric layer includes silicate, wherein a surface energy of the first dielectric layer is greater than 2.5 J/m², wherein the first connector is exposed by the first dielectric layer; forming a second dielectric layer and a second connector on a second main portion of a second electronic device, wherein the second dielectric layer includes an organic polymer material, wherein the second connector is exposed by the second dielectric layer; bonding the first dielectric layer of the first electronic device to the second dielectric layer of the second electronic device at a room temperature; fully curing the first dielectric layer; and bonding the first connector and the second connector.

### CROSS-REFERENCE TO RELATED APPLICATIONS

This application claims the benefit of U.S. Provisional Application No. 63/749,463, filed Jan. 24, 2025, the entire disclosure of which is incorporated by reference herein.

### BACKGROUND

### 1. Field of the Disclosure

The present disclosure relates to an assembly structure and an electronic device an a manufacturing method for manufacturing the same, and to an assembly structure and an electronic device including a dielectric layer and a manufacturing method for manufacturing the same.

### 2. Description of the Related Art

In an existing semiconductor electronic package structure, a plurality of electronic devices may be stacked on one another. Due to the numerous high-temperature thermal cycles involved in the manufacturing process, significant warpage of the electronic devices and solder cracking between the electronic devices can occur in the semiconductor package. As a result, both the manufacturing yield and the long-term reliability of the semiconductor electronic package may be adversely affected.

### SUMMARY

In some embodiments, a manufacturing method includes: forming a first dielectric layer and a first connector on a first main portion of a first electronic device, wherein the first dielectric layer includes an organic polymer material, the first dielectric layer includes silicate, wherein a surface energy of the first dielectric layer is greater than 2.5 J/m², wherein the first connector is exposed by the first dielectric layer; forming a second dielectric layer and a second connector on a second main portion of a second electronic device, wherein the second dielectric layer includes an organic polymer material, wherein the second connector is exposed by the second dielectric layer; bonding the first dielectric layer of the first electronic device to the second dielectric layer of the second electronic device at a room temperature; fully curing the first dielectric layer; and bonding the first connector and the second connector.

In some embodiments, an assembly structure includes a first electronic device and a second electronic device. The first electronic device includes a first main portion, a first connector and a first dielectric layer. The first connector is disposed on the first main portion. The first dielectric layer is disposed on the first main portion and surrounds the first connector. The first dielectric layer includes an organic polymer material, the first dielectric layer includes silicate. A surface energy of the first dielectric layer is greater than 1.0 J/m². The second electronic device includes a second main portion, a second connector and a second dielectric layer. The second connector is disposed on the second main portion. The second dielectric layer is disposed on the second main portion and surrounds the second connector. The second dielectric layer includes an organic polymer material. The first dielectric layer of the first electronic device is bonded to the second dielectric layer of the second electronic device. The first connector is bonded to the second connector.

In some embodiments, an electronic device includes a main portion, a conductive structure, a pad and an outermost dielectric layer. The conductive structure is disposed on the main portion, and includes a plurality of inner dielectric layers and a plurality of circuit layers. The inner dielectric layers are stacked on one another. The circuit layers are in contact with the inner dielectric layers. The pad is disposed on and electrically connected to the conductive structure. The outermost dielectric layer is disposed on the conductive structure and surrounds the pad. A material of the inner dielectric layers is different from a material of the outermost dielectric layer. The outermost dielectric layer includes an organic and non-photosensitive material. The outermost dielectric layer includes silicate. A surface energy of the first dielectric layer is greater than 2.5 J/m².

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an assembly structure according to some embodiments of the present disclosure.

FIG. 2 through FIG. 6 illustrate a manufacturing method for manufacturing an assembly structure according to some embodiments of the present disclosure.

FIG. 7 illustrates a cross-sectional view of an assembly structure according to some embodiments of the present disclosure.

FIG. 8 through FIG. 12 illustrate a manufacturing method for manufacturing an assembly structure according to some embodiments of the present disclosure.

FIG. 13 illustrates a cross-sectional view of an assembly structure according to some embodiments of the present disclosure.

FIG. 14 illustrates a cross-sectional view of an assembly structure according to some embodiments of the present disclosure.

FIG. 15 illustrates a cross-sectional view of an assembly structure according to some embodiments of the present disclosure.

FIG. 16 illustrates a cross-sectional view of an assembly structure according to some embodiments of the present disclosure.

FIG. 17 illustrates a cross-sectional view of an assembly structure according to some embodiments of the present disclosure.

FIG. 18 illustrates a cross-sectional view of an assembly structure according to some embodiments of the present disclosure.

FIG. 19 illustrates a cross-sectional view of an assembly structure according to some embodiments of the present disclosure.

FIG. 20 illustrates a cross-sectional view of an assembly structure according to some embodiments of the present disclosure.

FIG. 21 illustrates a cross-sectional view of an assembly structure according to some embodiments of the present disclosure.

FIG. 22 illustrates a cross-sectional view of an assembly structure according to some embodiments of the present disclosure.

FIG. 23 illustrates a cross-sectional view of an assembly structure according to some embodiments of the present disclosure.

FIG. 24 illustrates a cross-sectional view of an electronic device according to some embodiments of the present disclosure.

FIG. 25 illustrates a cross-sectional view of an electronic device according to some embodiments of the present disclosure.

FIG. 26 illustrates an enlarged view of an area “A” of FIG. 25.

FIG. 27 through FIG. 30 illustrate a manufacturing method for manufacturing a top electronic device according to some embodiments of the present disclosure.

FIG. 30A illustrates a cross-sectional view of a top electronic device according some embodiments of the present disclosure.

FIG. 30B illustrates a cross-sectional view of a top electronic device 4t according to some embodiments of the present disclosure.

FIG. 31 through FIG. 36 illustrate a manufacturing method for manufacturing a base electronic device according to some embodiments of the present disclosure.

FIG. 37 through FIG. 42 illustrate a manufacturing method for manufacturing a base electronic device according to some embodiments of the present disclosure.

FIG. 42A illustrates a cross-sectional view of a base electronic device according to some embodiments of the present disclosure.

FIG. 43 through FIG. 48 illustrate a manufacturing method for manufacturing a middle electronic device according to some embodiments of the present disclosure.

FIG. 49 through FIG. 50 illustrate a manufacturing method for manufacturing a middle electronic device according to some embodiments of the present disclosure.

FIG. 51 through FIG. 56 illustrate a manufacturing method for manufacturing a middle electronic device according to some embodiments of the present disclosure.

FIG. 57 through FIG. 59 illustrate a manufacturing method for manufacturing an assembly structure according to some embodiments of the present disclosure.

FIG. 60 illustrates a cross-sectional view of an assembly structure according to some embodiments of the present disclosure.

FIG. 61 illustrates a cross-sectional view of an assembly structure according to some embodiments of the present disclosure.

FIG. 62 illustrates a cross-sectional view of an assembly structure according to some embodiments of the present disclosure.

FIG. 63 illustrates a cross-sectional view of an assembly structure according to some embodiments of the present disclosure.

FIG. 64 illustrates a cross-sectional view of an assembly structure according to some embodiments of the present disclosure.

FIG. 65 illustrates a cross-sectional view of an assembly structure according to some embodiments of the present disclosure.

FIG. 66 illustrates a cross-sectional view of an assembly structure according to some embodiments of the present disclosure.

FIG. 67 illustrates a cross-sectional view of an assembly structure according to some embodiments of the present disclosure.

FIG. 68 illustrates a cross-sectional view of an assembly structure according to some embodiments of the present disclosure.

FIG. 69 illustrates a cross-sectional view of an assembly structure according to some embodiments of the present disclosure.

FIG. 70 illustrates a cross-sectional view of an assembly structure according to some embodiments of the present disclosure.

FIG. 71 illustrates a cross-sectional view of an assembly structure according to some embodiments of the present disclosure.

FIG. 72 illustrates a cross-sectional view of an assembly structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

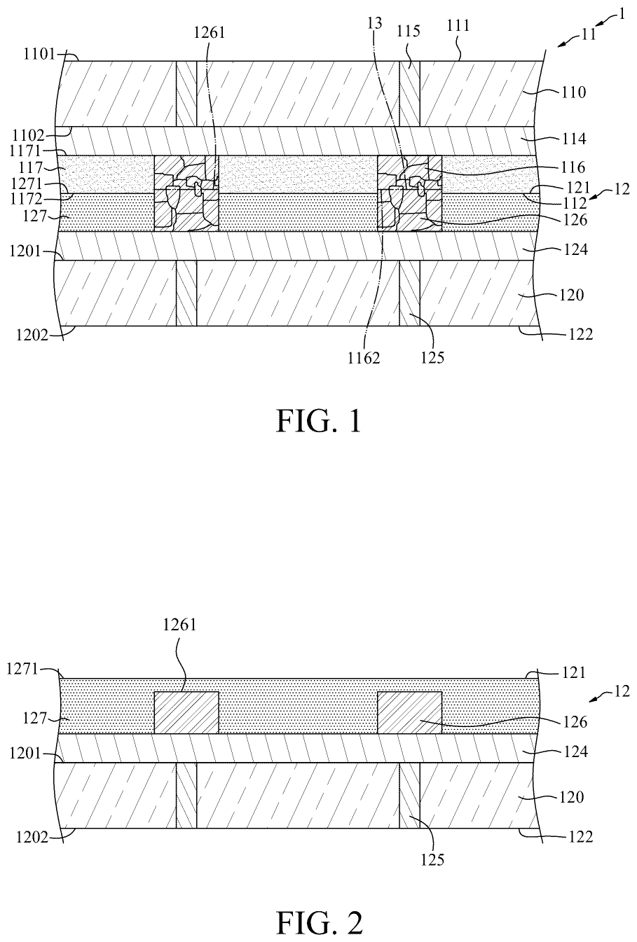

FIG. 1 illustrates a cross-sectional view of an assembly structure 1 according to some embodiments of the present disclosure. The assembly structure 1 may be an electronic package structure, a semiconductor package structure, an electronic structure, an electronic device, a semiconductor device, a stacked structure or a three-dimensional form factor device. The assembly structure 1 may include a first electronic device 11 and a second electronic device 12 bonded to the first electronic device 11. The assembly structure 1 may be used in a voltage regulator. The voltage regulator may include a control logic and a redundant control logic, and may perform a step of engaging the redundant control logic and disengaging the control logic.

The first electronic device 11 may be a substrate, a semiconductor die, a semiconductor chip or an integrated circuit die. In some embodiments, the first electronic device 11 may be a logic device such as a logic die or a logic chip. In some embodiments, the first electronic device 11 may include an application-specific integrated circuit (ASIC) chip. Alternatively, the first electronic device 11 may include a memory device such as a high bandwidth memory (HBM).

The first electronic device 11 may have a first surface 111 (e.g., a top surface, an upper surface, a first outer surface or a first outermost surface), a second surface 112 (e.g., a lower surface, a bottom surface, a second outer surface or a second outermost surface) opposite to the first surface 111, and a lateral surface extending between the first surface 111 and the second surface 112. The first electronic device 11 may include a first main portion 110, a first conductive structure 114, a plurality of through vias 115, a first connector 116 and a first dielectric layer 117.

The first main portion 110 may be a semiconductor substrate, and may include, for example, silicon (Si) or other semiconductor materials. The first main portion 110 may have a first surface 1101 (e.g., a top surface, an upper surface, a first outer surface, a first outermost surface, or a backside surface) and a second surface 1102 (e.g., a lower surface, a bottom surface, a second outer surface, a second outermost surface, or an active surface) opposite to the first surface 1101. The first surface 1101 of the first main portion 110 may be the first surface 111 of the first electronic device 11. The through vias 115 may extend through the first main portion 110, and may be also referred to as “through silicon vias (TSVs)”. The through vias 115 may be formed outside a stress concentration region in the first main portion 110.

The first conductive structure 114 may be disposed on the second surface 1102 of the first main portion 110. The first conductive structure 114 may be also referred to as “an outer structure”, “an addition structure”, “a stacked structure”, “a built-up structure”, “a circuit pattern structure”. In some embodiments, the first conductive structure 114 may include a plurality of front-end-of-line (FEOL) devices, such as resistors, capacitors, inductors, and/or transistors. In some embodiments, the first conductive structure 114 may further include at least one back-end-of-line (BEOL) interconnect pattern, e.g., a plurality of patterned circuit layers, electrically connected to the front-end-of-line (FEOL) devices. The first conductive structure 114 may include a dielectric structure, a plurality of circuit layers (including a plurality traces and a plurality of pads) embedded in the dielectric structure, and a plurality of inner vias. The dielectric structure may be a multi-layer film stack deposited on the first main portion 110. Thus, the first conductive structure 114 may include a plurality of inner dielectric layers. A material of the inner dielectric layers may include an inorganic material or organic material, and may be a photosensitive material. The inner dielectric layer may include photoinitiators. In some embodiments, the inner dielectric layer may include SiO₂, SiCN and/or SiN. For example, SiO₂ may have a Young's modulus of 70 GPa to 100 GPa, and have a mohs hardness of 7.0. SiCN may have a Young's modulus ranging from 190 GPa to 300 GPa, and have a mohs hardness of 9.0. SiN may have a Young's modulus of 290 GPa, and have a mohs hardness of 7.0. The inner vias may be disposed in the dielectric structure, and may electrically connect the circuit layers. The circuit layers of the first conductive structure 114 may be electrically connected to the through vias 115. In some embodiments, the through vias 115 may extend through the first conductive structure 114.

The first connector 116 (e.g., a first pad) may be disposed on the first conductive structure 114 on the first main portion 110. A material of the first connector 116 (e.g., the first pad) may include Cu, Al or Au. The first connector 116 (e.g., the first pad) may have a second surface 1162 (e.g., a lower surface, a bottom surface, a second outer surface or a second outermost surface).

The first dielectric layer 117 may be disposed on the first conductive structure 11 on the first main portion 110, and may surround the first connector 116. The first dielectric layer 117 may be the outermost dielectric layer. Thus, the first conductive structure 114 may be disposed between the first main portion 110 and the first dielectric layer 117. The material of the inner dielectric layer of the first conductive structure 114 is different from a material of the first dielectric layer 117. The first dielectric layer 117 may include an organic polymer material, e.g., a combination of polybenzoxazoles (PBO) and acrylic resin, or a combination of epoxy and acrylic resin. The first dielectric layer 117 may be a non-photosensitive material. The first dielectric layer 117 may not include photoinitiators. The first dielectric layer 117 may include silicate so as to increase the concentration (or the percentage) of hydroxyl groups and improve the adhesion property of the first dielectric layer 117. That is, the first dielectric layer 117 is more adhesive than the conventional inorganic dielectric layer (e.g., SiO₂, SiCN and SiN) and the conventional photosensitive polyimide (PI) dielectric layer during the bonding process at room temperature (e.g., at about 20° C. to about 25° C.). In some embodiments, a surface energy of the first dielectric layer 117 may be greater than 1.0 J/m², 1.5 J/m², 2.0 J/m², 2.5 J/m², 3.0 J/m², 3.5 J/m², 4.0 J/m², 5.0 J/m², 6.0 J/m², 7.0 J/m², 8.0 J/m², or 9.0 J/m². The surface energy of the first dielectric layer 117 may be greater than 2 times, 3 times, 5 times, 6 times, 7 times, 8 times, 9 times, or 10 times the surface energy of the conventional inorganic dielectric layer (e.g., SiO₂, SiCN and SiN) and the surface energy of the conventional photosensitive polyimide (PI) dielectric layer. Thus, the adhesion force (or bonding strength) of the first dielectric layer 117 when bonding two elements may be greater than 2 times, 3 times, 5 times, 6 times, 7 times, 8 times, 9 times, or 10 times the adhesion force (or bonding strength) of the conventional inorganic dielectric layer (e.g., SiO₂, SiCN and SiN) when bonding two elements and the adhesion force (or bonding strength) of the conventional photosensitive polyimide (PI) dielectric layer when bonding two elements.

The first dielectric layer 117 may have a glass transition temperature (Tg) greater than 300° C., 350° C., or 400° C. In comparison, the glass transition temperature (Tg) of the conventional photosensitive polyimide (PI) dielectric layer may be in a range from 150° C. to 250° C. The difference between the glass transition temperature (Tg) of the first dielectric layer 117 and the glass transition temperature (Tg) of the conventional photosensitive polyimide (PI) dielectric layer may be greater than 50° C., 100° C., 150° C., or 200° C. In addition, the first dielectric layer 117 may have a Young's modulus ranging from about 4.0 GPa to about 6.0 GPa. In comparison, the Young's modulus of the conventional photosensitive polyimide (PI) dielectric layer may be about 2.5 GPa. Thus, the Young's modulus of the first dielectric layer 117 may be greater than the Young's modulus of the conventional photosensitive polyimide (PI) dielectric layer. The ratio of the Young's modulus of the first dielectric layer 117 to the Young's modulus of the conventional photosensitive polyimide (PI) dielectric layer may be about 1.6 to 2.4, 1.6 to 2.0, or 2.0 to 2.4.

The first dielectric layer 117 may have a first surface 1171 (e.g., an upper surface, a top surface, a first outer surface or a first outermost surface) and a second surface 1172 (e.g., a lower surface, a bottom surface, a second outer surface or a second outermost surface) opposite to the first surface 1171. The second surface 1162 (e.g., the second outermost surface) of the first connector 116 (e.g., the first pad) may be substantially aligned with or substantially coplanar with the second surface 1172 (e.g., the second outermost surface) of the first dielectric layer 117. Thus, the second surface 1162 (e.g., the second outermost surface) of the first connector 116 (e.g., the first pad) may be exposed by the second surface 1172 (e.g., the second outermost surface) of the first dielectric layer 117. The first connector 116 (e.g., the first pad) may extend through the first dielectric layer 117. A thickness of the first connector 116 (e.g., the first pad) may be substantially equal to a thickness of the first dielectric layer 117. The second surface 112 of the first electronic device 11 may include the second surface 1162 (e.g., the second outermost surface) of the first connector 116 (e.g., the first pad) and the second surface 1172 (e.g., the second outermost surface) of the first dielectric layer 117.

The second electronic device 12 may be bonded to the first electronic device 11. The second electronic device 12 may be a substrate, a semiconductor die, a semiconductor chip or an integrated circuit die. In some embodiments, the second electronic device 12 may be a logic device such as a logic die or a logic chip. In some embodiments, the second electronic device 12 may include an application-specific integrated circuit (ASIC) chip. Alternatively, the second electronic device 12 may include a memory device such as a high bandwidth memory (HBM).

The second electronic device 12 may have a first surface 121 (e.g., a top surface, an upper surface, a first outer surface or a first outermost surface), a second surface 122 (e.g., a lower surface, a bottom surface, a second outer surface or a second outermost surface) opposite to the first surface 121, and a lateral surface extending between the first surface 121 and the second surface 122. The second electronic device 12 may include a second main portion 120, a second conductive structure 124, a plurality of through vias 125, a second connector 126 and a second dielectric layer 127.

The second main portion 120 may be a semiconductor substrate, and may include, for example, silicon (Si) or other semiconductor materials. The second main portion 120 may have a first surface 1201 (e.g., a top surface, an upper surface, a first outer surface, a first outermost surface, or an active surface) and a second surface 1202 (e.g., a lower surface, a bottom surface, a second outer surface, a second outermost surface, or a backside surface) opposite to the first surface 1201. The second surface 1202 of the second main portion 120 may be the second surface 122 of the second electronic device 12. The through vias 125 may extend through the second main portion 120, and may be also referred to as “through silicon vias (TSVs)”. The through vias 125 may be formed outside a stress concentration region in the second main portion 120.

The second conductive structure 124 may be disposed on the first surface 1201 of the second main portion 120. The second conductive structure 124 may be also referred to as “an outer structure”, “an addition structure”, “a stacked structure”, “a built-up structure”, “a circuit pattern structure”. In some embodiments, the second conductive structure 124 may include a plurality of front-end-of-line (FEOL) devices, such as resistors, capacitors, inductors, and/or transistors. In some embodiments, the second conductive structure 124 may further include at least one back-end-of-line (BEOL) interconnect pattern, e.g., a plurality of patterned circuit layers, electrically connected to the front-end-of-line (FEOL) devices. The second conductive structure 124 may include a dielectric structure, a plurality of circuit layers (including a plurality traces and a plurality of pads) embedded in the dielectric structure, and a plurality of inner vias. The dielectric structure may be a multi-layer film stack deposited on the second main portion 120. Thus, the second conductive structure 124 may include a plurality of inner dielectric layers. A material of the inner dielectric layers may include an inorganic material or organic material, and may be a photosensitive material. The inner dielectric layer may include photoinitiators. In some embodiments, the inner dielectric layer may include SiO₂, SiCN and/or SiN. The inner vias may be disposed in the dielectric structure, and may electrically connect the circuit layers. The circuit layers of the second conductive structure 124 may be electrically connected to the through vias 125. In some embodiments, the through vias 125 may extend through the second conductive structure 124.

The second connector 126 (e.g., a second pad) may be disposed on the second conductive structure 124 on the second main portion 120. A material of the second connector 126 (e.g., the second pad) may include Cu, Al or Au. The second connector 126 (e.g., the second pad) may have a first surface 1261 (e.g., an upper surface, a top surface, a first outer surface or a first outermost surface).

The second dielectric layer 127 may be disposed on the second conductive structure 124 on the second main portion 120, and may surround the second connector 126. The second dielectric layer 127 may be the outermost dielectric layer. Thus, the second conductive structure 124 may be disposed between the second main portion 120 and the second dielectric layer 127. A material of the second dielectric layer 127 may be different from the material of the first dielectric layer 117. The material of the inner dielectric layer of the second conductive structure 124 may be different from a material of the second dielectric layer 127. The second dielectric layer 127 may include an organic polymer material, and may be a photosensitive material. In some embodiments, a material of the second dielectric layer 127 may be made of a cured photoimageable dielectric (PID) material such as epoxy, benzocyclobutene (BCB), polybenzoxazoles (PBO) or polyimide (PI) including photoinitiators. In some embodiments, the surface energy of the first dielectric layer 117 may be greater than 2 times, 3 times, 5 times, 6 times, 7 times, 8 times, 9 times, or 10 times the surface energy of the second dielectric layer 127. Thus, the adhesion force (or bonding strength) of the first dielectric layer 117 when bonding two elements may be greater than 2 times, 3 times, 5 times, 6 times, 7 times, 8 times, 9 times, or 10 times the adhesion force (or bonding strength) of the second dielectric layer 127 when bonding two elements.

The glass transition temperature (Tg) of the second dielectric layer 127 may be in a range from 150° C. to 250° C. The difference between the glass transition temperature (Tg) of the first dielectric layer 117 and the glass transition temperature (Tg) of the second dielectric layer 127 may be greater than 50° C., 100° C., 150° C., or 200° C. In addition, the Young's modulus of the second dielectric layer 127 may be about 2.5 GPa. Thus, the Young's modulus of the second dielectric layer 127 may be less than the Young's modulus of the first dielectric layer 117. The ratio of the Young's modulus of the first dielectric layer 117 to the Young's modulus of the second dielectric layer 127 may be about 1.6 to 2.4, 1.6 to 2.0, or 2.0 to 2.4.

The second dielectric layer 127 may have a first surface 1271 (e.g., an upper surface, a top surface, a first outer surface or a first outermost surface). The first surface 1261 (e.g., the first outermost surface) of the second connector 126 (e.g., the second pad) may be substantially aligned with or substantially coplanar with the first surface 1271 (e.g., the first outermost surface) of the second dielectric layer 127. Thus, the first surface 1261 (e.g., the first outermost surface) of the second connector 126 (e.g., the second pad) may be exposed by the first surface 1271 (e.g., the first outermost surface) of the second dielectric layer 127. The second connector 126 (e.g., the second pad) may extend through the second dielectric layer 127. A thickness of the second connector 126 (e.g., the second pad) may be substantially equal to a thickness of the second dielectric layer 127. The first surface 121 of the second electronic device 12 may include the first surface 1261 (e.g., the first outermost surface) of the second connector 126 (e.g., the second pad) and the first surface 1271 (e.g., the first outermost surface) of the second dielectric layer 127.

The first surface 121 of the second electronic device 12 may be bonded to the second surface 112 of the first electronic device 11. Thus, the first dielectric layer 117 of the first electronic device 11 may be bonded to or adhered to the second dielectric layer 127 of the second electronic device 12. The first connector 116 may be bonded to the second connector 126. There may be an interface 13 between the first connector 116 and the second connector 126. The interface 13 may be disposed between the first surface 1171 and the second surface 1172 of the first dielectric layer 117. Alternatively, the interface 13 may not be obvious or visible. Since the surface energy of the first dielectric layer 117 is relatively high, the bonding force or bonding strength between the first dielectric layer 117 and the second dielectric layer 127 may be improved. Thus, after an annealing process, new metal grains may grow across the interface 13, and the first connector 116 and the second connector 126 may be merged into a single homogeneous metallic structure.

In addition, the first dielectric layer 117 can cover larger particle, thus, first dielectric layer 117 does not require a high-spec cleanroom, a plasma activation process and a water rinse process. The manufacture cost of the assembly structure 1 may be reduced. In some embodiments, the second dielectric layer 127 may include PI, which is cheap, thus, the manufacture cost of the assembly structure 1 may be further reduced. In addition, during manufacturing process, the first dielectric layer 117 may be bonded to the second dielectric layer 127 at a low temperature such as room temperature or a temperature of not greater than 150° C. Thus, a warpage of the first electronic device 11 and the second electronic device 12 may be reduced. For example, the warpage of the first electronic device 11 and the second electronic device 12 may be less than 10 μm.

FIG. 2 through FIG. 6 illustrate a manufacturing method for manufacturing an assembly structure according to some embodiments of the present disclosure. In some embodiments, the method is for manufacturing the assembly structure 1 shown in FIG. 1.

Referring to FIG. 2, a second electronic device 12 may be provided. The second electronic device 12 may be similar to the second electronic device 12 of FIG. 1. The second electronic device 12 may be a substrate or a semiconductor structure. In some embodiments, the second electronic device 12 may be in a panel type (or a panel structure) or a wafer type (or a wafer structure). The second electronic device 12 may include a second main portion 120, a second conductive structure 124 and a plurality of through vias 125. Then, a second connector 126 and a second dielectric layer 127 may be formed on the second main portion 120. In some embodiments, the second connector 126 may be formed on the second main portion 120. Then, the second dielectric layer 127 may be formed on the second main portion 120 by spin coating to cover and contact the second connector 126. The second dielectric layer 127 may include an organic polymer material such as PI. Then, the second dielectric layer 127 may be pre-cured.

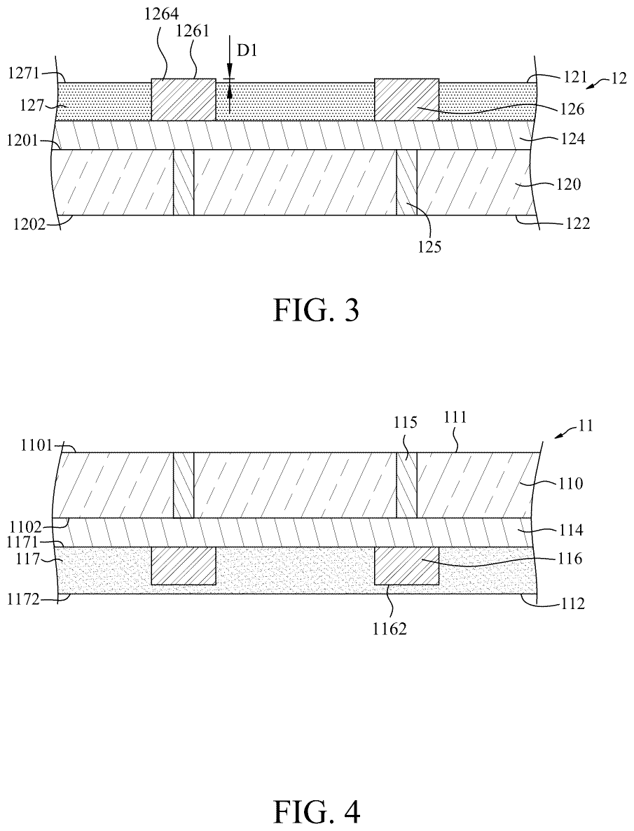

Referring to FIG. 3, a grinding process (e.g., a chemical mechanical polishing (CMP) process) may be conducted on the first surface 121 of the second electronic device 12 (e.g., the first surface 1261 (e.g., the first outermost surface) of the second connector 126 (e.g., the second pad) and the first surface 1271 (e.g., the first outermost surface) of the second dielectric layer 127). After the grinding process, the first surface 1261 (e.g., the first outermost surface) of the second connector 126 may protrude from the first surface 1271 (e.g., the first outermost surface) of the second dielectric layer 127 by a height D1. The height D1 may be less than 15 nm or less than 10 nm. The second connector 126 may protrude from the first surface 121 (e.g., the first outermost surface) of the second electronic device 12 by the height D1. That is, the height D1 may be the height difference between the first surface 1261 (e.g., the first outermost surface) of the second connector 126 and the first surface 1271 (e.g., the first outermost surface) of the second dielectric layer 127. Thus, the second connector 126 may include a protrusion portion 1264 protruding from the first surface 1271 of the second dielectric layer 127. The protrusion portion 1264 may have a height D1. The protrusion portion 1264 of the second connector 126 may be exposed by the second dielectric layer 127.

Referring to FIG. 4, a first electronic device 11 may be provided. The first electronic device 11 may be similar to the first electronic device 11 of FIG. 1. The first electronic device 11 may be a substrate or a semiconductor structure. In some embodiments, the first electronic device 11 may be in a panel type (or a panel structure) or a wafer type (or a wafer structure). The first electronic device 11 may include a first main portion 110, a first conductive structure 114 and a plurality of through vias 115. Then, a first connector 116 and a first dielectric layer 117 may be formed on the first main portion 110. In some embodiments, the first connector 116 may be formed on the first main portion 110. Then, the first dielectric layer 117 may be formed on the first main portion 110 by spin coating to cover and contact the first connector 116. The first dielectric layer 117 may include an organic polymer material. The first dielectric layer 117 may include silicate. A surface energy of the first dielectric layer 117 may be greater than 2.5 J/m². Then, the first dielectric layer 117 may be pre-cured.

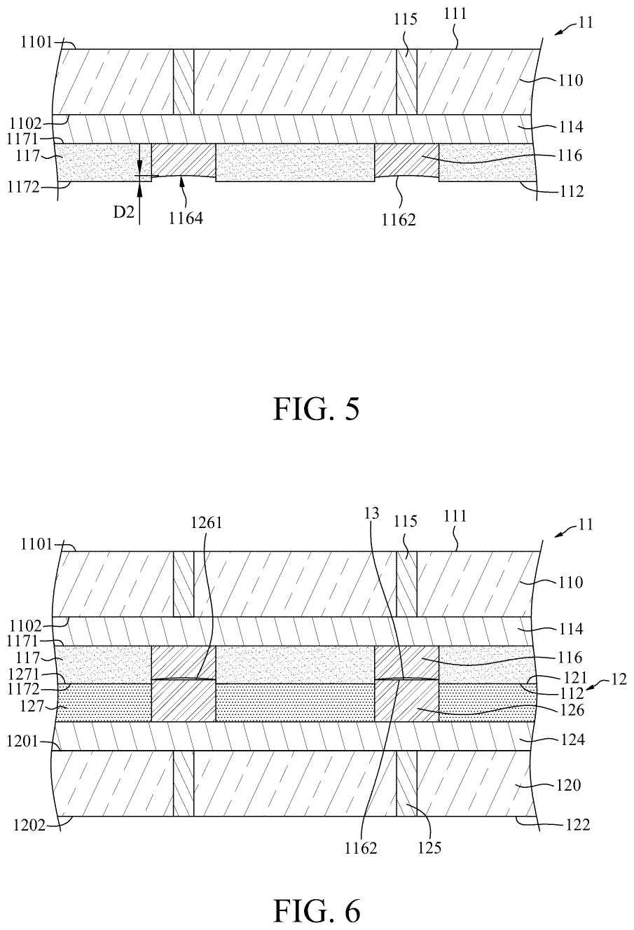

Referring to FIG. 5, a grinding process (e.g., a chemical mechanical polishing (CMP) process) may be conducted on the second surface 112 of the first electronic device 11 (e.g., the second surface 1162 (e.g., the second outermost surface) of the first connector 116 (e.g., the first pad) and the second surface 1172 (e.g., the second outermost surface) of the first dielectric layer 117. After the grinding process, the second surface 1162 (e.g., the second outermost surface) of the first connector 116 (e.g., the first pad) may have a dished surface profile. The second surface 1162 (e.g., the second outermost surface) of the first connector 116 (e.g., the first pad) may be recess from the second surface 1172 (e.g., the second outermost surface) of the first dielectric layer 117 by a distance D2. The distance D2 may be less than 27 nm, 15 nm, or less than 10 nm. The second surface 1162 (e.g., the second outermost surface) of the first connector 116 (e.g., the first pad) may be recess from the second surface 112 (e.g., the second outermost surface) of the first electronic device 11 by the distance D2. That is, the distance D2 may be the height difference between the second surface 1162 (e.g., the second outermost surface) of the first connector 116 (e.g., the first pad) and the second surface 1172 (e.g., the second outermost surface) of the first dielectric layer 117. Thus, the first dielectric layer 117 and the first connector 116 may collectively define a recess portion 1164 recessed from the second surface 1172 (e.g., the second outermost surface) of the first dielectric layer 117. The recess portion 1164 may have a depth D2. The first connector 116 may be exposed by the first dielectric layer 117.

Referring to FIG. 6, the first dielectric layer 117 of the first electronic device 11 may be bonded to or adhered to the second dielectric layer 127 of the second electronic device 12 at a room temperature, which may prevent the first connector 116 and the second connector 126 from oxidizing. The protrusion portion 1264 of the second connector 126 may be inserted into the recess portion 1164 of the first dielectric layer 117. Since the surface energy of the first dielectric layer 117 is relatively high, the bonding force or bonding strength between the first dielectric layer 117 and the second dielectric layer 127 may be relatively high at room temperature. Then, the first dielectric layer 117 and the second dielectric layer 127 may be fully cured. After fully curing the first dielectric layer 117, the first dielectric layer 117 may shrink. The shrinkage rate of the first dielectric layer 117 may be about 2%. Thus, the distance of the metal diffusion between the first connector 116 and the second connector 126 may be shortened. Thus, the grinding process (e.g., a chemical mechanical polishing (CMP) process) may have a greater process window. For example, even when the depth D2 of the recess portion 1164 is less than 27 nm, the metal diffusion between the first connector 116 and the second connector 126 may still occur. In addition, after fully curing the first dielectric layer 117, the first dielectric layer 117 may have a glass transition temperature (Tg) greater than 400° C., and the first dielectric layer 117 may have a Young's modulus ranging from about 4.0 GPa to about 6.0 GPa.

An interface 13 may be formed between the first connector 116 and the second connector 126. The interface 13 may be disposed between the first surface 1171 and the second surface 1172 of the first dielectric layer 117. Then, an annealing process may be conducted so as to bond the first connector 116 and the second connector 126. Since the surface energy of the first dielectric layer 117 is relatively high, the bonding force or bonding strength between the first dielectric layer 117 and the second dielectric layer 127 may be improved. Thus, after an annealing process, new metal grains may grow across the interface 13, and the first connector 116 and the second connector 126 may be merged into a single homogeneous metallic structure. Thus, the interface 13 may not be obvious or visible. Therefore, the assembly structure 1 of FIG. 1 is obtained. In some embodiments, the singulation process has not be conducted yet. In addition, the method may improve the void issue or particle issue during the bonding process. Therefore, the yield rate of the assembly structure 1 may be improved.

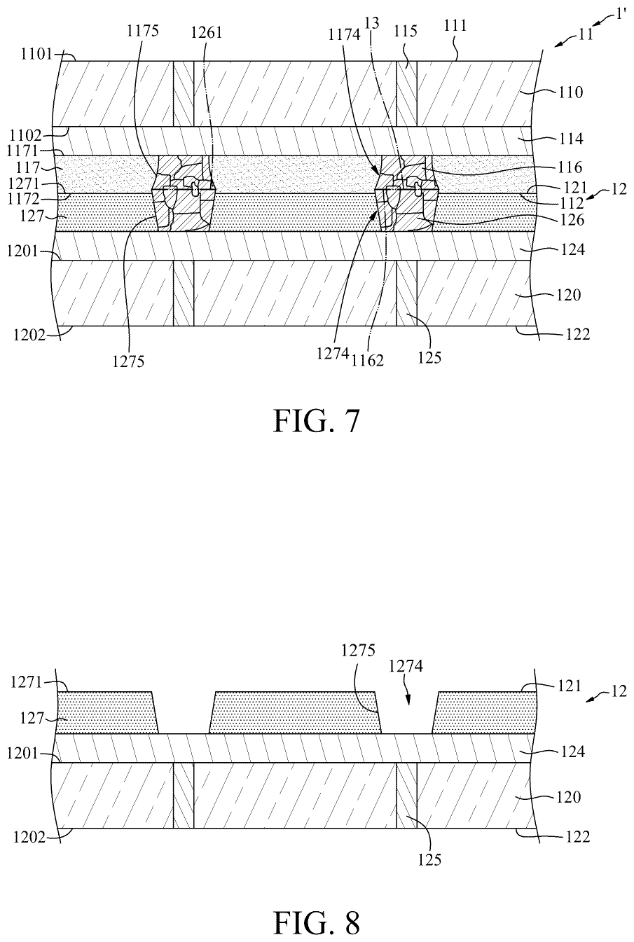

FIG. 7 illustrates a cross-sectional view of an assembly structure 1′ according to some embodiments of the present disclosure. The assembly structure 1′ of FIG. 7 is similar to the assembly structure 1 of FIG. 1 except for the through hole 1274 of the second dielectric layer 127 and the through hole 1174 of the first dielectric layer 117. The through hole 1274 of the second dielectric layer 127 may taper toward the second conductive structure 124 on the second main portion 120. The second connector 126 in the through hole 1274 may also taper toward the second conductive structure 124 on the second main portion 120. A surface roughness of the sidewall 1275 of the through hole 1274 may be greater than or less than a surface roughness of the first surface 1271 (e.g., the first outermost surface) of the second dielectric layer 127. In addition, the through hole 1174 of the first dielectric layer 117 may taper toward the first conductive structure 114 on the first main portion 110. The first connector 116 in the through hole 1174 may also taper toward the first conductive structure 1 14 on the first main portion 110. A surface roughness of the sidewall 1175 of the through hole 1174 may be greater than a surface roughness of the second surface 1172 (e.g., the second outermost surface) of the first dielectric layer 117. The surface roughness of the sidewall 1175 of the through hole 1174 may be greater than the surface roughness of the sidewall 1275 of the through hole 1274. In addition, the sidewall 1175 of the through hole 1174 may be a slanted convex surface. The sidewall 1275 of the through hole 1274 may be a substantially flat surface. The curvature of the sidewall 1175 of the through hole 1174 may be different from the curvature of the sidewall 1275 of the through hole 1274.

FIG. 8 through FIG. 12 illustrate a manufacturing method for manufacturing an assembly structure according to some embodiments of the present disclosure. In some embodiments, the method is for manufacturing the assembly structure 1′ shown in FIG. 7.

Referring to FIG. 8, a second electronic device 12 may be provided. The second electronic device 12 may be similar to the second electronic device 12 of FIG. 7. The second electronic device 12 may include a second main portion 120, a second conductive structure 124 and a plurality of through vias 125. Then, a second dielectric layer 127 may be formed on the second main portion 120 by spin coating. The second dielectric layer 127 may include an organic polymer material such as PI. Then, the second dielectric layer 127 may be pre-cured. Then, a through hole 1274 may be formed to extend through the second dielectric layer 127 by a photolithography process.

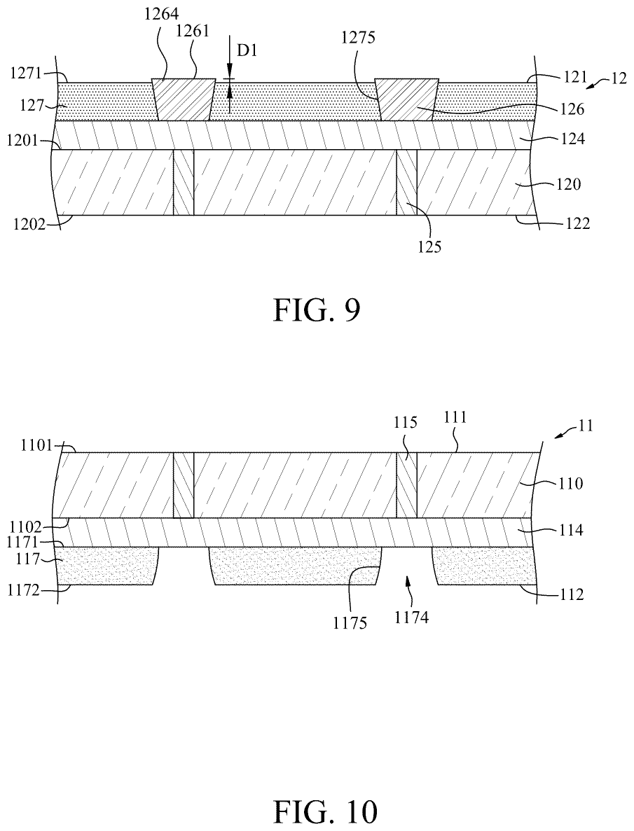

Referring to FIG. 9, a second connector 126 may be formed in the through hole 1274 on the second main portion 120. Then, a grinding process (e.g., a chemical mechanical polishing (CMP) process) may be conducted on the first surface 121 of the second electronic device 12 (e.g., the first surface 1261 (e.g., the first outermost surface) of the second connector 126 (e.g., the second pad) and the first surface 1271 (e.g., the first outermost surface) of the second dielectric layer 127). After the grinding process, the first surface 1261 (e.g., the first outermost surface) of the second connector 126 may protrude from the first surface 1271 (e.g., the first outermost surface) of the second dielectric layer 127 by a height D1. The height D1 of FIG. 9 may be substantially equal to the height D1 of FIG. 3.

Referring to FIG. 10, a first electronic device 11 may be provided. The first electronic device 11 may be similar to the first electronic device 11 of FIG. 7. The first electronic device 11 may be a substrate or a semiconductor structure. In some embodiments, the first electronic device 11 may be in a panel type (or a panel structure) or a wafer type (or a wafer structure). The first electronic device 11 may include a first main portion 110, a first conductive structure 114 and a plurality of through vias 115. Then, a first dielectric layer 117 may be formed on the first main portion 110 by spin coating. A material of the first dielectric layer 117 of FIG. 10 may the same as the material of the first dielectric layer 117 of FIG. 7. Then, the first dielectric layer 117 may be pre-cured. Then, a through hole 1174 may be formed to extend through the first dielectric layer 117 by a laser drilling process.

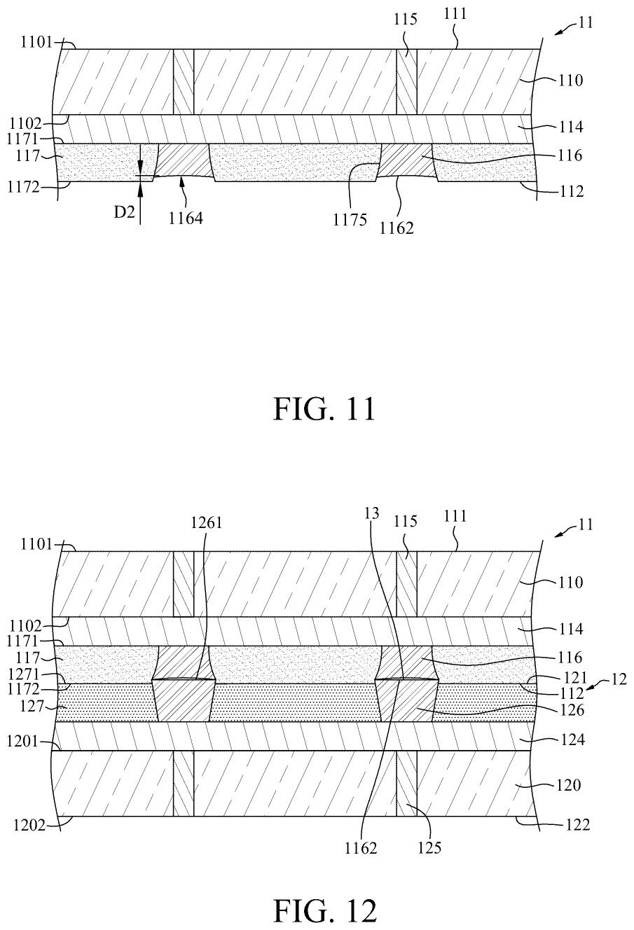

Referring to FIG. 11, a first connector 116 may be formed in the through hole 1174 on the first main portion 110. Then, a grinding process (e.g., a chemical mechanical polishing (CMP) process) may be conducted on the second surface 112 of the first electronic device 11 (e.g., the second surface 1162 (e.g., the second outermost surface) of the first connector 116 (e.g., the first pad) and the second surface 1172 (e.g., the second outermost surface) of the first dielectric layer 117. After the grinding process, the second surface 1162 (e.g., the second outermost surface) of the first connector 116 (e.g., the first pad) may have a dished surface profile. The dished surface profile of FIG. 11 may be substantially equal to the dished surface profile of FIG. 5.

Referring to FIG. 12, the first dielectric layer 117 of the first electronic device 11 may be bonded to or adhered to the second dielectric layer 127 of the second electronic device 12 at a room temperature, which may prevent the first connector 116 and the second connector 126 from oxidizing. Then, the first dielectric layer 117 and the second dielectric layer 127 may be fully cured. An interface 13 may be formed between the first connector 116 and the second connector 126. The interface 13 may be disposed between the first surface 1171 and the second surface 1172 of the first dielectric layer 117. Then, an annealing process may be conducted so as to bond the first connector 116 and the second connector 126. Therefore, the assembly structure 1′ of FIG. 7 is obtained.

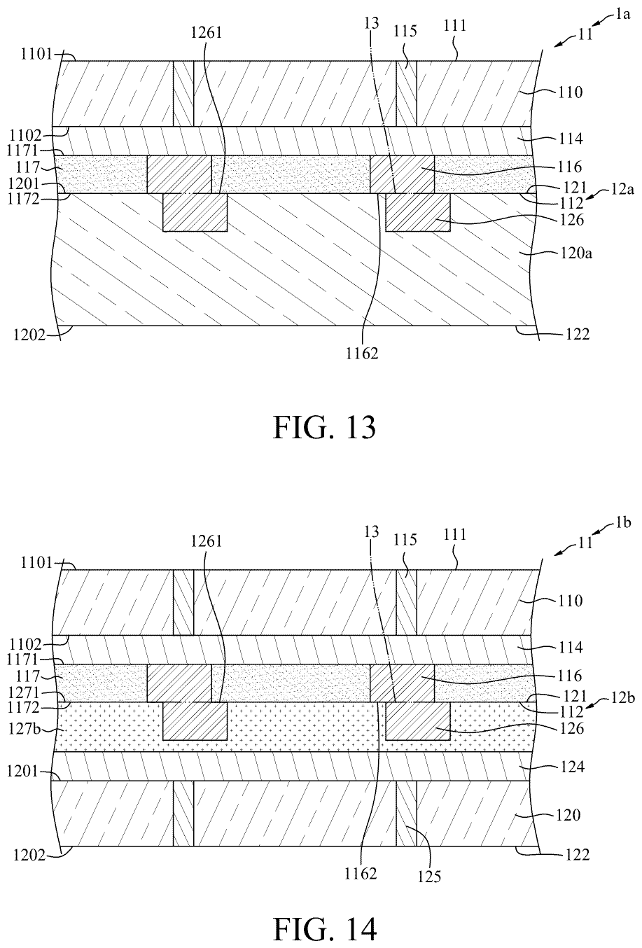

FIG. 13 illustrates a cross-sectional view of an assembly structure 1a according some embodiments of the present disclosure. The assembly structure 1a of FIG. 13 is similar to the assembly structure 1 of FIG. 1 except for the structure of the second electronic device 12a. The second electronic device 12a may not include the second conductive structure 124 and the second dielectric layer 127. The second connector 126 may be embedded in the second main portion 120a. The entire second main portion 120a may be silicon material. The first surface 1261 (e.g., the first outermost surface) of the second connector 126 (e.g., the second pad) may be substantially aligned with or substantially coplanar with the first surface 1201 (e.g., the first outermost surface) of the second main portion 120a. The first surface 121 of the second electronic device 12a may include the first surface 1261 (e.g., the first outermost surface) of the second connector 126 (e.g., the second pad) and the first surface 1201 (e.g., the first outermost surface) of the second main portion 120a. The first dielectric layer 117 of the first electronic device 11 may be bonded to or adhered to the second main portion 120a of the second electronic device 12. In addition, the first connector 116 may be misaligned with the second connector 126. Thus, there may be a shift between the first connector 116 and the second connector 126.

FIG. 14 illustrates a cross-sectional view of an assembly structure 1b according some embodiments of the present disclosure. The assembly structure 1b of FIG. 14 is similar to the assembly structure 1 of FIG. 1 except for the structure of the second electronic device 12b. The second dielectric layer 127b of the second electronic device 12b may include inorganic material such SiO₂, SiCN and/or SiN. A thickness of the second connector 126 may be less than a thickness of the second dielectric layer 127b. The second dielectric layer 127b has a Young's modulus greater than the Young's modulus of the first dielectric layer 117. In addition, the first connector 116 may be misaligned with the second connector 126.

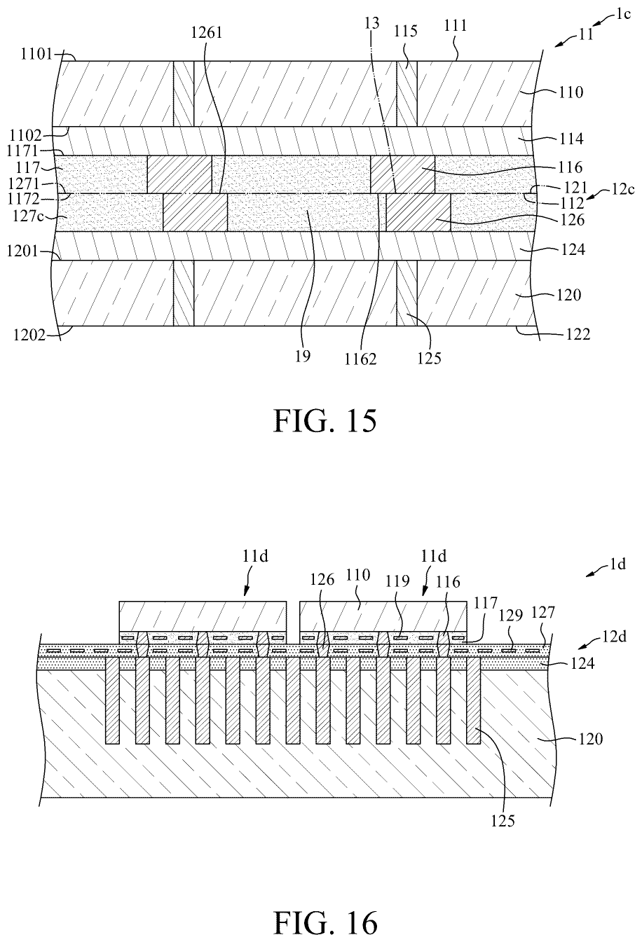

FIG. 15 illustrates a cross-sectional view of an assembly structure 1c according some embodiments of the present disclosure. The assembly structure 1c of FIG. 15 is similar to the assembly structure 1 of FIG. 1 except for the structure of the second electronic device 12c. The material of the second dielectric layer 127c of the second electronic device 12c may be the same as the material of the first dielectric layer 117 of the first electronic device 11. Thus, the first dielectric layer 117 and the second dielectric layer 127c may collectively form a monolithic dielectric structure 19 without an interface therebetween. In addition, the first connector 116 may be misaligned with the second connector 126.

FIG. 16 illustrates a cross-sectional view of an assembly structure 1d according some embodiments of the present disclosure. The assembly structure 1d of FIG. 16 is similar to the assembly structure 1′ of FIG. 7, and the differences are described as follows. The assembly structure 1d may include two first electronic devices 11d disposed side by side on a second electronic device 12d. The first electronic device 11d may include a first main portion 110, a first connector 116, at least one circuit layer 119 and a first dielectric layer 117. The first main portion 110 of FIG. 16 may be similar to the first main portion 110 of FIG. 7. The material of the first dielectric layer 117 of FIG. 16 may be the same as the material of the first dielectric layer 117 of FIG. 7, and may include a plurality of sublayers stacked on one another. The circuit layer 119 may be embedded in the first dielectric layer 117. The first connector 116 may extend through the first dielectric layer 117.

The second electronic device 12d may be an interposer, and may include a second main portion 120, a second conductive structure 124, a plurality of through vias 125, a second connector 126, at least one circuit layer 129 and a second dielectric layer 127. The second main portion 120 of FIG. 16 may be similar to the second main portion 120 of FIG. 7. The through vias 125 may or may not extend through the second main portion 120. The second conductive structure 124 may include an organic polymer material such as PI. The through vias 125 may extend through the second conductive structure 124. The material of the second dielectric layer 127 of FIG. 16 may be the same as the material of the second dielectric layer 127 of FIG. 7, and may include a plurality of sublayers stacked on one another. The circuit layer 129 may be embedded in the second dielectric layer 127. The second connector 126 may extend through the second dielectric layer 127, and may contact the through via 125.

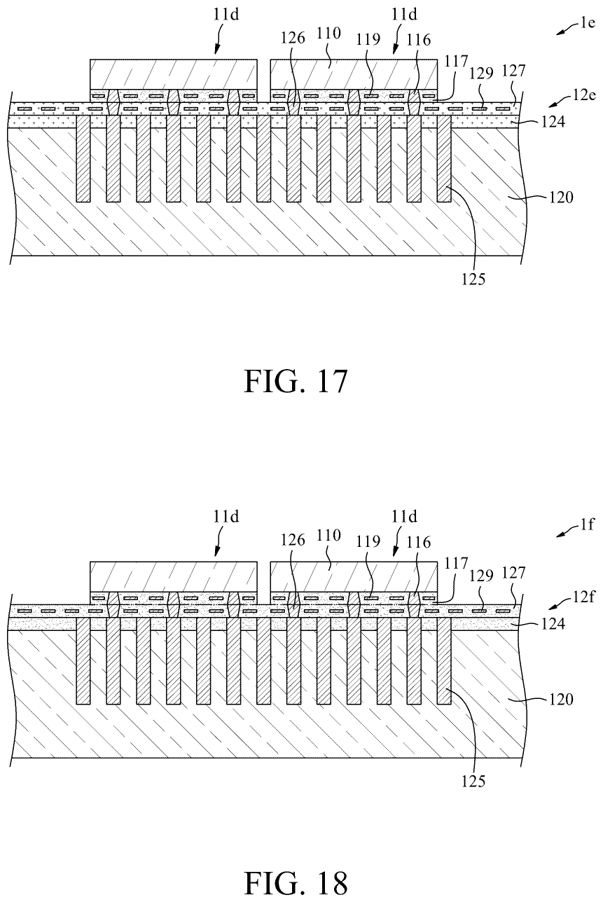

FIG. 17 illustrates a cross-sectional view of an assembly structure 1e according some embodiments of the present disclosure. The assembly structure 1e of FIG. 17 is similar to the assembly structure 1d of FIG. 16, except that the second conductive structure 124 of the second electronic device 12e may include an inorganic material such as SiO₂, SiCN and/or SiN, and the material of the second dielectric layer 127 of the second electronic device 12e may also include an inorganic material such as SiO₂, SiCN and/or SiN.

FIG. 18 illustrates a cross-sectional view of an assembly structure 1f according some embodiments of the present disclosure. The assembly structure 1f of FIG. 18 is similar to the assembly structure 1d of FIG. 16, except that the second conductive structure 124 of the second electronic device 12f may include an organic polymer material that is the same as the material of the first dielectric layer 117. The material of the second dielectric layer 127 of the second electronic device 12f may also include an organic polymer material that is the same as the material of the first dielectric layer 117.

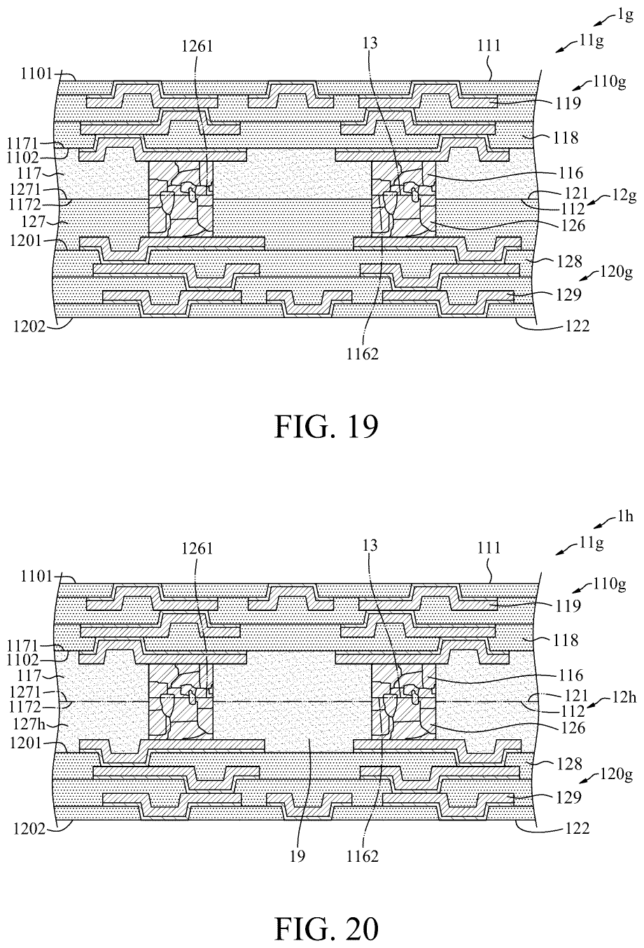

FIG. 19 illustrates a cross-sectional view of an assembly structure 1g according some embodiments of the present disclosure. The assembly structure 1g of FIG. 19 is similar to the assembly structure 1 of FIG. 1 except for the structure of the first main portion 110g of the first electronic device 11g and the structure of the second main portion 120g of the second electronic device 12g. In the first electronic device 11g, the first dielectric layer 117 may directly contact the second surface 1102 of the first main portion 110g. The first main portion 110g may include a plurality of inner dielectric layers 118 stacked on one another and plurality of circuit layers 119 in contact with the plurality of inner dielectric layers 118. The material of the inner dielectric layers 118 may be different from the material of the first dielectric layer 117. The inner dielectric layer 118 may include a photosensitive material. In some embodiments, the material of the inner dielectric layer 118 may be made of a cured photoimageable dielectric (PID) material such as epoxy, benzocyclobutene (BCB), polybenzoxazoles (PBO) or polyimide (PI) including photoinitiators.

The circuit layers 119 may be embedded in the inner dielectric layers 118 and may be electrically connected to each other by inner vias. The circuit layer 119 may be a fan-out circuit layer, or a redistribution layer (RDL). Thus, the first electronic device 11g may be also referred to as “a fan-out structure”, or “a redistribution layer (RLD) structure”. The topmost circuit layer 119 may be exposed by the first surface 1101 of the first main portion 110g (i.e., the first surface 111 of the first electronic device 11g). The bottommost circuit layer 119 may be disposed on the second surface 1102 of the first main portion 110g. The first connector 116 may be disposed on the bottommost circuit layer 119.

In the second electronic device 12g, the second dielectric layer 127 may directly contact the first surface 1201 of the second main portion 120g. The second main portion 120g may include a plurality of inner dielectric layers 128 stacked on one another and plurality of circuit layers 129 in contact with the plurality of inner dielectric layers 128. The material of the inner dielectric layers 128 may be the same as the material of the second dielectric layer 127. The inner dielectric layer 128 may include a photosensitive material. In some embodiments, the material of the inner dielectric layer 128 may be made of a cured photoimageable dielectric (PID) material such as epoxy, benzocyclobutene (BCB), polybenzoxazoles (PBO) or polyimide (PI) including photoinitiators.

The circuit layers 129 may be embedded in the inner dielectric layers 128 and may be electrically connected to each other by inner vias. The circuit layer 129 may be a fan-out circuit layer, or a redistribution layer (RDL). Thus, the second electronic device 12g may be also referred to as “a fan-out structure”, or “a redistribution layer (RLD) structure”. The bottommost circuit layer 129 may be exposed by the second surface 1202 of the second main portion 120g (i.e., the second surface 122 of the second electronic device 12g). The topmost circuit layer 129 may be disposed on the first surface 1201 of the second main portion 120g. The second connector 126 may be disposed on the topmost circuit layer 129.

FIG. 20 illustrates a cross-sectional view of an assembly structure 1h according some embodiments of the present disclosure. The assembly structure 1h of FIG. 20 is similar to the assembly structure 1g of FIG. 19 except for the structure of the second electronic device 12h. The material of the second dielectric layer 127h of the second electronic device 12h may be the same as the material of the first dielectric layer 117 of the first electronic device 11g. Thus, the first dielectric layer 117 and the second dielectric layer 127h may collectively form a monolithic dielectric structure 19 without an interface therebetween.

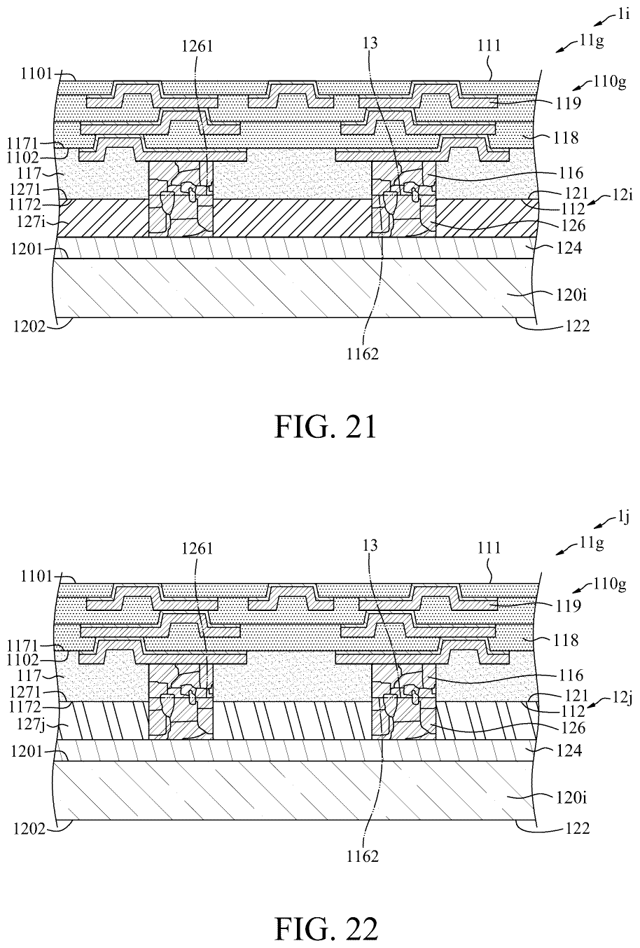

FIG. 21 illustrates a cross-sectional view of an assembly structure 1i according to some embodiments of the present disclosure. The assembly structure 1i of FIG. 21 is similar to the assembly structure 1g of FIG. 19 except for the structure of the second electronic device 12i. The second main portion 120i may be an organic substrate including a cured resin and a plurality glass fibers disposed therein. For example, the second main portion 120i may be FR4 substrate. The second conductive structure 124 may be disposed on the first surface 1201 of the second main portion 120i. The second conductive structure 124 may include may include a plurality of inner dielectric layers stacked on one another and plurality of circuit layers in contact with the plurality of inner dielectric layers. The material of the inner dielectric layers may be different from the material of the first dielectric layer 117. The inner dielectric layer may include a photosensitive material. In some embodiments, the material of the inner dielectric layer may be made of a cured photoimageable dielectric (PID) material such as epoxy, benzocyclobutene (BCB), polybenzoxazoles (PBO) or polyimide (PI) including photoinitiators. The second dielectric layer 127i may be disposed on the second conductive structure 124. The material of the second dielectric layer 127i may include a solder mask layer or a solder resist layer.

FIG. 22 illustrates a cross-sectional view of an assembly structure 1j according to some embodiments of the present disclosure. The assembly structure 1j of FIG. 22 is similar to the assembly structure 1i of FIG. 21, except that the second dielectric layer 127j may include an Ajinomoto build-up film (ABF).

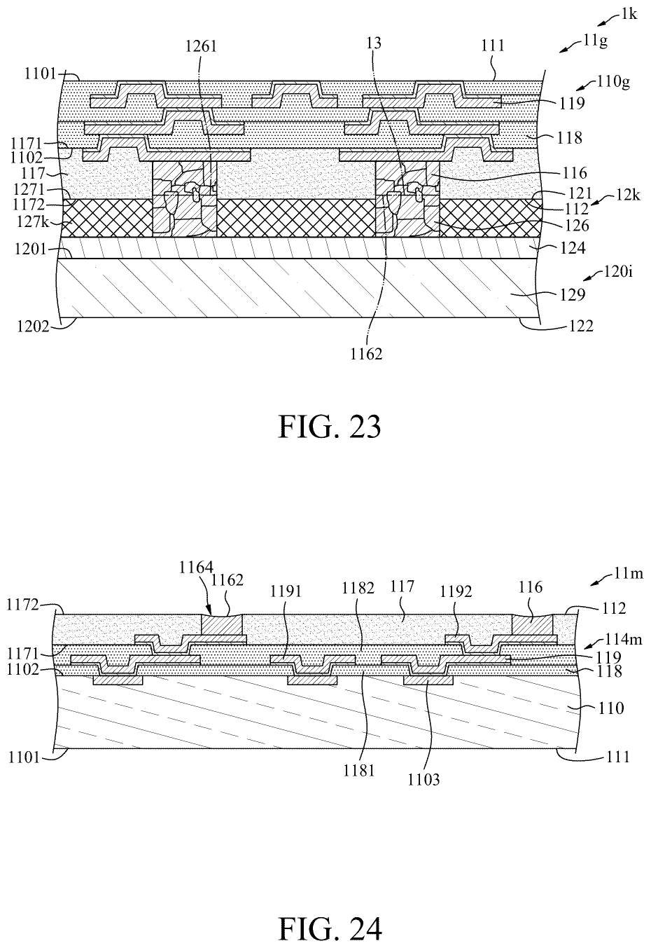

FIG. 23 illustrates a cross-sectional view of an assembly structure 1k according some embodiments of the present disclosure. The assembly structure 1k of FIG. 23 is similar to the assembly structure 1i of FIG. 21, except that the second dielectric layer 127k may include a bismaleimide triazine (BT).

FIG. 24 illustrates a cross-sectional view of an electronic device 11m according some embodiments of the present disclosure. The electronic device 11m of FIG. 24 is similar to the first electronic device 11 of the assembly structure 1 of FIG. 1. The electronic device 11m may have a first surface 111 (e.g., a bottom surface, a lower surface, a first outer surface or a first outermost surface), a second surface 112 (e.g., an upper surface, a top surface, a second outer surface or a second outermost surface) opposite to the first surface 111, and a lateral surface extending between the first surface 111 and the second surface 112. The electronic device 11m may include a main portion 110, a conductive structure 114m, a connector 116 (or a pad or a bump) and an outermost dielectric layer 117.

The main portion 110 may be a semiconductor substrate, and may include, for example, silicon (Si) or other semiconductor materials. The main portion 110 may have a first surface 1101 (e.g., a lower surface, a bottom surface, a second outer surface, a second outermost surface, or a backside surface) and a second surface 1102 (e.g., a top surface, an upper surface, a first outer surface, a first outermost surface, or an active surface) opposite to the first surface 1101. The first surface 1101 of the first main portion 110 may be the first surface 111 of the first electronic device 11. The main portion 110 may include a conductive pad 1103 disposed adjacent to or exposed by the second surface 1102 of the main portion 110.

The conductive structure 114m may be disposed on the second surface 1102 of the main portion 110. The conductive structure 114m may be also referred to as “an outer structure”, “an addition structure”, “a stacked structure”, “a built-up structure”, “a circuit pattern structure”. The conductive structure 114m may include a plurality of inner dielectric layers 118 stacked on one another, a plurality of circuit layers 119 (including a plurality traces and a plurality of pads) in contact with the inner dielectric layers 118, and a plurality of inner vias electrically connecting circuit layers 119. The material of the inner dielectric layers 118 may be different from the material of the first dielectric layer 117. The inner dielectric layers 118 may include a photosensitive material. In some embodiments, the material of the inner dielectric layers 118 may be made of a cured photoimageable dielectric (PID) material such as epoxy, benzocyclobutene (BCB), polybenzoxazoles (PBO) or polyimide (PI) including photoinitiators. The inner dielectric layers 118 may include a first inner dielectric layer 1181 and a second inner dielectric layer 1182.

The circuit layers 119 may be embedded in the inner dielectric layers 118 and may be electrically connected to each other by inner vias. The circuit layer 119 may be a fan-out circuit layer, or a redistribution layer (RDL). Thus, the conductive structure 114m may be also referred to as “a fan-out structure”, or “a redistribution layer (RLD) structure”. The circuit layers 119 may include a first circuit layer 1191 and a second circuit layer 1192.

The first inner dielectric layer 1181 may be disposed on the second surface 1102 of the main portion 110, and may define an opening to expose the conductive pad 1103. The first circuit layer 1191 may be disposed on the first inner dielectric layer 1181 and in the opening so as to contact the conductive pad 1103. The second inner dielectric layer 1182 may be disposed on the first inner dielectric layer 1181 to cover the first circuit layer 1191. The second inner dielectric layer 1182 may define an opening to expose the first circuit layer 1191. The second circuit layer 1192 may be disposed on the second inner dielectric layer 1182 and in the opening so as to contact the first circuit layer 1191.

The connector 116 (e.g., the pad) may be disposed on and electrically connected to the conductive structure 114m. In some embodiments, the connector 116 (e.g., the pad) may be disposed on the topmost circuit layer such as the second circuit layer 1192. The connector 116 (e.g., the pad) may have a second surface 1162 (e.g., an upper surface, a top surface, a second outer surface or a second outermost surface). The outermost dielectric layer 117 may be disposed on the conductive structure 114m, and may surround the connector 116 (e.g., the pad). The material of the inner dielectric layers 118 of the conductive structure 114m may different from the material of the outermost dielectric layer 117. The outermost dielectric layer 117 may include an organic polymer material, e.g., a combination of polybenzoxazoles (PBO) and acrylic resin, or a combination of epoxy and acrylic resin. The outermost dielectric layer 117 may be a non-photosensitive material. The outermost dielectric layer 117 may not include photoinitiators. The outermost dielectric layer 117 may include silicate so as to increase the concentration (or the percentage) of hydroxyl groups and improve the adhesion property of the outermost dielectric layer 117. In some embodiments, a surface energy of the outermost dielectric layer 117 may be greater than 1.0 J/m², 1.5 J/m², 2.0 J/m², 2.5 J/m², 3.0 J/m², 3.5 J/m², 4.0 J/m², 5.0 J/m², 6.0 J/m², 7.0 J/m², 8.0 J/m², or 9.0 J/m². The surface energy of the outermost dielectric layer 117 may be greater than 2 times, 3 times, 5 times, 6 times, 7 times, 8 times, 9 times, or 10 times the surface energy of the conventional photosensitive polyimide (PI) dielectric layer (e.g., the inner dielectric layers 118). Thus, the adhesion force (or bonding strength) of the outermost dielectric layer 117 when bonding two elements may be greater than 2 times, 3 times, 5 times, 6 times, 7 times, 8 times, 9 times, or 10 times the adhesion force (or bonding strength) of the conventional photosensitive polyimide (PI) dielectric layer (e.g., the inner dielectric layers 118) when bonding two elements.

The outermost dielectric layer 117 may have a glass transition temperature (Tg) greater than 300° C., 350° C., or 400° C. In addition, the outermost dielectric layer 117 may have a Young's modulus ranging from about 4.0 GPa to about 6.0 GPa. Thus, the Young's modulus of the outermost dielectric layer 117 may be greater than the Young's modulus of the inner dielectric layers 118. The ratio of the Young's modulus of the outermost dielectric layer 117 to the Young's modulus of the inner dielectric layers 118 may be about 1.6 to 2.4, 1.6 to 2.0, or 2.0 to 2.4.

The outermost dielectric layer 117 may have a first surface 1171 (e.g., a lower surface, a bottom surface, a first outer surface or a first outermost surface) and a second surface 1172 (e.g., an upper surface, a top surface, a second outer surface or a second outermost surface) opposite to the first surface 1171. The second surface 1162 (e.g., the top surface or the second outermost surface) of the connector 116 (e.g., the pad) may have a dished surface profile. The second surface 1162 of the connector 116 (e.g., the pad) may be recess from the second surface 1172 (e.g., the second outermost surface) of the outermost dielectric layer 117 by a distance D2 (FIG. 5). The distance D2 may be less than 27 nm, 15 nm, or less than 10 nm. The second surface 1162 of the connector 116 may be recess from the second surface 112 (e.g., the second outermost surface) of the electronic device 11m by the distance D2. That is, the distance D2 may be the height difference between the second surface 1162 of the first connector 116 and the second surface 1172 of the outermost dielectric layer 117. Thus, the outermost dielectric layer 117 and the connector 116 may collectively define a recess portion 1164 recessed from the second surface 1172 of the outermost dielectric layer 117. The recess portion 1164 may have a depth D2. The connector 116 may be exposed by the outermost dielectric layer 117. In addition, a surface roughness of the second surface 1172 (e.g., the top surface) of the outermost dielectric layer 117 may be less than a surface roughness of the top surface of the conductive structure 114m since a grinding process may be conducted on the second surface 1172 (e.g., the top surface) of the outermost dielectric layer 117.

In the electronic device 11m, the connector 116 (or the pad or the bump) and t outermost dielectric layer 117 may be configured for external connection. Thus, the conventional UBM pad and solder ball may be omitted. The manufacturing time and manufacturing cost may be reduced. Further, a total thickness of an assembly structure may be reduced. In addition, the conventional solder bridge may be avoided. Thus, the yield rate of the assembly structure may be improved.

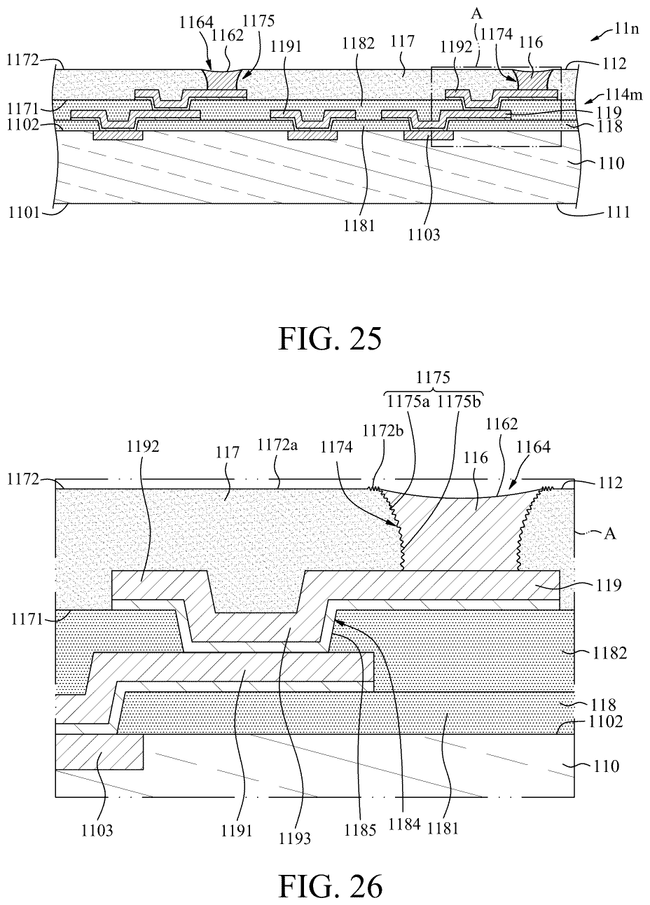

FIG. 25 illustrates a cross-sectional view of an electronic device 11n according some embodiments of the present disclosure. FIG. 26 illustrates an enlarged view of an area “A” of FIG. 25. The electronic device 11n of FIG. 25 is similar to the electronic device 11m of FIG. 24 except for the through hole 1174 of the outermost dielectric layer 117. The outermost dielectric layer 117 may define the through hole 1174 for accommodating the connector 116 (or the pad or the bump). The through hole 1174 of FIG. 25 and FIG. 26 may be similar to or the same as the through hole 1174 of FIG. 10 and FIG. 11. A sidewall 1175 of the through hole 1174 may include an upper portion 1175a and a lower portion 1175b. A surface roughness of the upper portion 1175a of the sidewall 1175 of the through hole 1174 may be greater than a surface roughness of the lower portion 1175b of the sidewall 1175 of the through hole 1174 since the through hole 1174 may be formed by a laser drilling. The surface roughness of the second surface 1172 (e.g., the top surface) of the outermost dielectric layer 117 may be less than the surface roughness of the lower portion 1175b of the sidewall 1175 of the through hole 1174.

In addition, the second surface 1172 (e.g., the top surface) of the outermost dielectric layer 117 may include a first portion 1172b adjacent to the through hole 1174 and a second portion 1172a away from the through hole 1174. The first portion 1172b may be a corner of the through hole 1174. A surface roughness of the first portion 1172b may be greater than a surface roughness of the second portion 1172a since a laser may contact the first portion 1172b during the laser drilling. The surface roughness of the first portion 1172b may be substantially equal to or less than the surface roughness of the upper portion 1175a of the sidewall 1175 of the through hole 1174.

The second inner dielectric layer 1182 may define an opening 1184 for accommodating an inner via 1193 for electrically connecting the circuit layers 1191, 1192. The opening 1184 of FIG. 26 may be similar to the through hole 1274 of FIG. 8. A surface roughness of a sidewall 1185 of the opening 1184 may be less than a surface roughness of the lower portion 1175b of the sidewall 1175 of the through hole 1174 since the opening 1184 may be formed by a photolithography process.

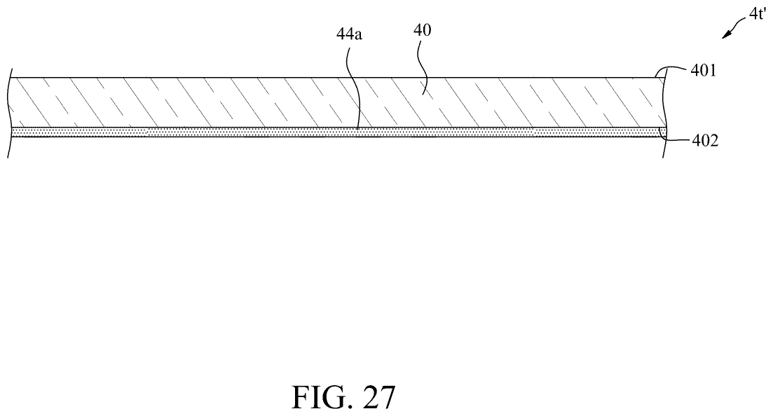

FIG. 27 through FIG. 30 illustrate a manufacturing method for manufacturing a top electronic device 4t according to some embodiments of the present disclosure.

Referring to FIG. 27, a top main portion 40 may be provided. The top main portion 40 may be a semiconductor substrate, and may include, for example, silicon (Si) or other semiconductor materials. The top main portion 40 may be in a panel type (or a panel structure) or a wafer type (or a wafer structure). The top main portion 40 may have a first surface 401 and a second surface 402 opposite to the first surface 401. Then, a dielectric layer 44a may be formed or disposed on the second surface 402 of the top main portion 40 by, for example, spin coating, so as to form a top electronic device 4t′. The dielectric layer 44a may include an organic polymer material such as PI.

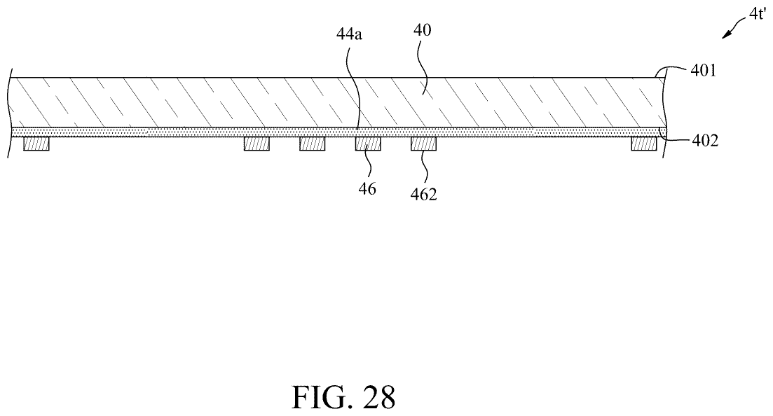

Referring to FIG. 28, at least one connector 46 (or at least one pad) may be formed or disposed on the dielectric layer 44a. The connector 46 (or the pad) may be formed as follows. A seed layer may be formed on the dielectric layer 44a by sputtering. A patterned photoresist layer may be formed on the seed layer. A metal material (e.g., copper) may be formed in the opening of the patterned photoresist layer. The patterned photoresist layer may be removed by stripping. The seed layer that is not covered by the metal material (e.g., copper) is removed by etching. Therefore, the connector 46 (including the metal material (e.g., copper) and the remaining seed layer) may be formed. The connector 46 may have a second surface 462 (e.g., a lower surface, a bottom surface, a second outer surface or a second outermost surface).

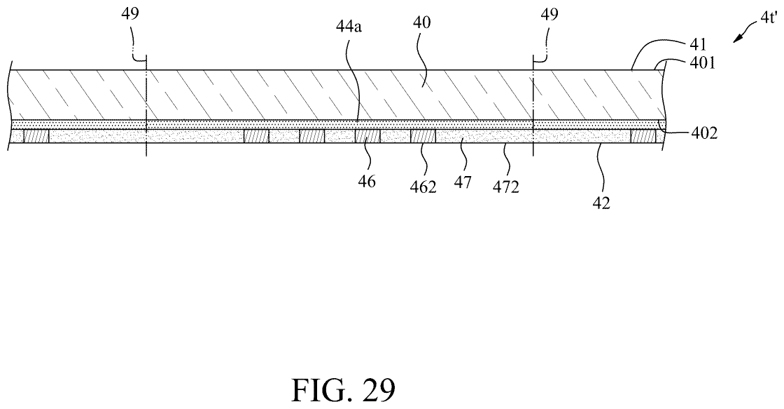

Referring to FIG. 29, an outermost dielectric layer 47 may be formed on the dielectric layer 44a on the top main portion 40 by spin coating to cover and contact the connector 46. The material of the outermost dielectric layer 47 may be the same as the material of the outermost dielectric layer 117 of FIG. 1. The outermost dielectric layer 47 may include an organic polymer material. The outermost dielectric layer 47 may include silicate. A surface energy of the outermost dielectric layer 47 may be greater than 2.5 J/m². Then, the outermost dielectric layer 47 may be pre-cured. The outermost dielectric layer 47 may have a second surface 472 (e.g., a lower surface, a bottom surface, a second outer surface or a second outermost surface). Then, a grinding process (e.g., a chemical mechanical polishing (CMP) process) may be conducted on the second surface 462 of the connector 46 and the second surface 472 of the outermost dielectric layer 47. After the grinding process, the second surface 462 of the connector 116 may have a dished surface profile.

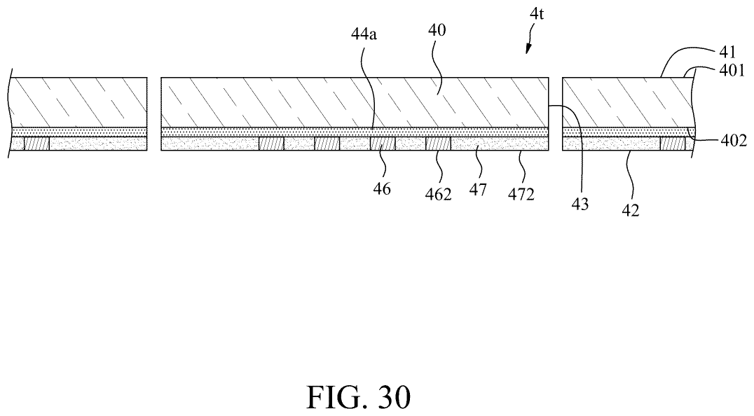

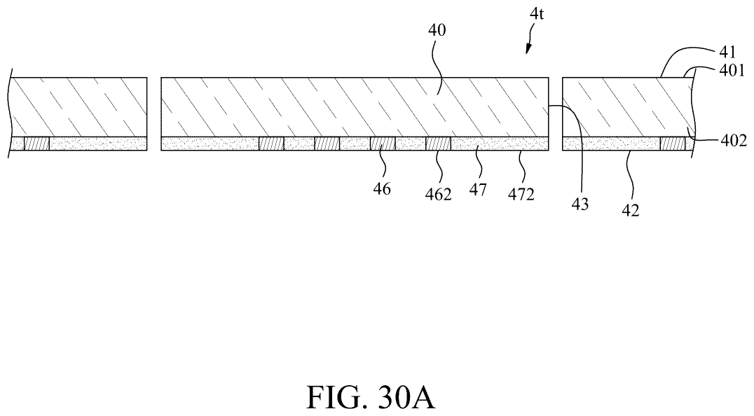

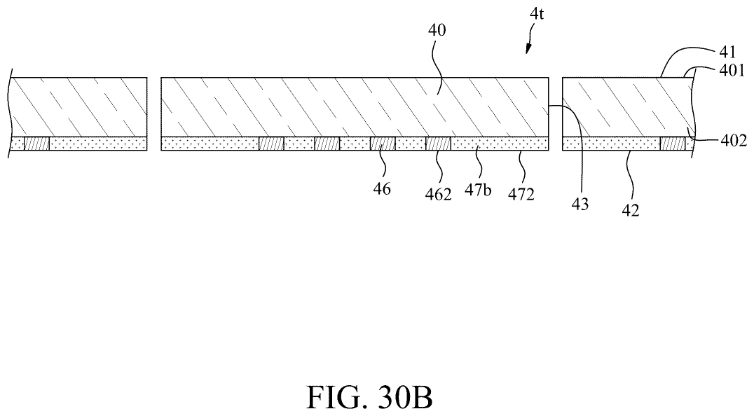

Referring to FIG. 30, a singulation process may be conducted along the cutting lines 49 so as to form a plurality of top electronic devices 4t. The top electronic device 4t may have a first surface 41 (e.g., a top surface, an upper surface, a first outer surface or a first outermost surface), a second surface 42 (e.g., a lower surface, a bottom surface, a second outer surface or a second outermost surface) opposite to the first surface 41, and a lateral surface 43 extending between the first surface 41 and the second surface 42. The top electronic device 4t may be also referred to as “a first electronic device”, “a second electronic device” or “a third electronic device”.

FIG. 30A illustrates a cross-sectional view of a top electronic device 4t according to some embodiments of the present disclosure. The top electronic device 4t of FIG. 30A is similar to the top electronic device 4t of FIG. 30 except that the dielectric layer 44a may be omitted. Thus, the connector 46 and the outermost dielectric layer 47 may be formed on the second surface 402 of the top main portion 40.

FIG. 30B illustrates a cross-sectional view of a top electronic device 4t according to some embodiments of the present disclosure. The top electronic device 4t of FIG. 30B is similar to the top electronic device 4t of FIG. 30A except for the material of the outermost dielectric layer 47b. The material of the outermost dielectric layer 47b may include an inorganic material such as SiO₂, SiCN and/or SiN.

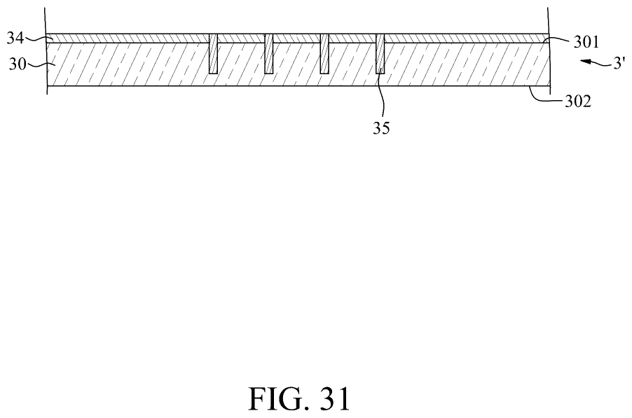

FIG. 31 through FIG. 36 illustrate a manufacturing method for manufacturing a base electronic device 3′ according to some embodiments of the present disclosure.

Referring to FIG. 31, a base electronic device 3′ may be provided. The base electronic device 3′ may be also referred to as “a first electronic device”, “a second electronic device” or “a third electronic device”. The base electronic device 3′ may be in a panel type (or a panel structure) or a wafer type (or a wafer structure). The base electronic device 3′ may be a logic device or a ASIC chip. The base electronic device 3′ may include a base main portion 30 and a conductive structure 34. The base main portion 30 may be a semiconductor substrate, and may include, for example, silicon (Si) or other semiconductor materials. The base main portion 30 may have a first surface 301 and a second surface 302 opposite to the first surface 301. The conductive structure 34 may be formed or disposed on the first surface 301 of the base main portion 30. The conductive structure 34 of FIG. 31 may be the same as the first conductive structure 114 of FIG. 1. Then, a conductive via 35 may be formed to extend through the conductive structure 34 and extend into the base main portion 30.

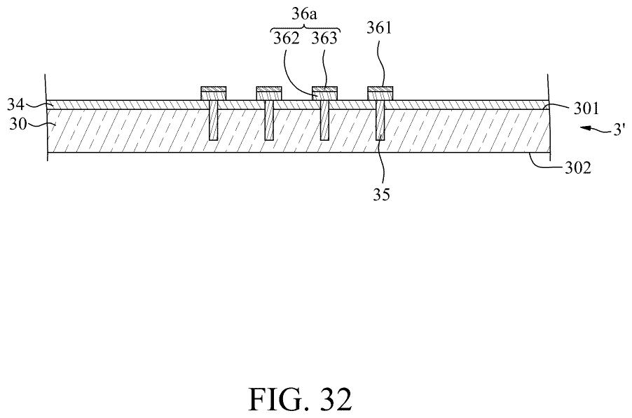

Referring to FIG. 32, at least one connector 36a (or at least one top connector, least one pad, or at least one top pad) may be formed or disposed on the conductive structure 34. The connector 36a (or the pad) may include a first layer 362 and a second layer 363 disposed on the first layer 362. The first layer 362 may include Ni. The second layer 363 may include Au. The connector 36a may be formed as follows. A seed layer may be formed on the conductive structure 34 by sputtering. A patterned photoresist layer may be formed on the seed layer. The first layer 362 (e.g., Ni) and the second layer 363 (e.g., Au) may be formed in the opening of the patterned photoresist layer. The patterned photoresist layer may be removed by stripping. The seed layer that is not covered by the first layer 362 (e.g., Ni) and the second layer 363 (e.g., Au) is removed by etching. Therefore, the connector 36a (including the first layer 362, the second layer 363 and the remaining seed layer) may be formed. The connector 36a (or the pad) may have a first surface 361 (e.g., an upper surface, a top surface, a first outer surface or a first outermost surface).

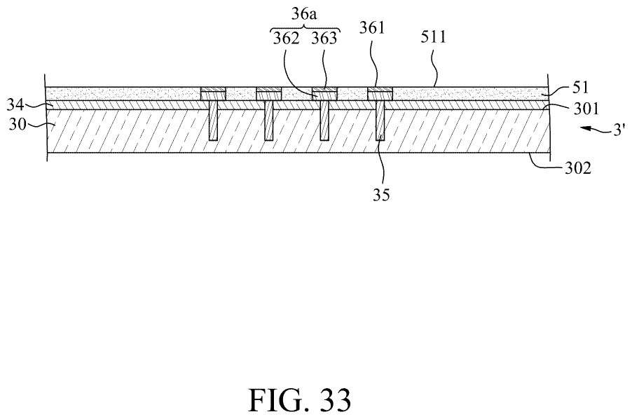

Referring to FIG. 33, an outermost dielectric layer 51 may be formed on the conductive structure 34 on the base main portion 30 by spin coating to cover and contact the connector 36a. The material of the outermost dielectric layer 51 may be the same as the material of the outermost dielectric layer 117 of FIG. 1. The outermost dielectric layer 51 may include an organic polymer material. The outermost dielectric layer 51 may include silicate. A surface energy of the outermost dielectric layer 51 may be greater than 2.5 J/m². Then, the outermost dielectric layer 51 may be pre-cured. The outermost dielectric layer 51 may have a first surface 511 (e.g., an upper surface, a top surface, a first outer surface or a first outermost surface). Then, a grinding process (e.g., a chemical mechanical polishing (CMP) process) may be conducted on the first surface 361 of the connector 36a and the first surface 511 of the outermost dielectric layer 51. After the grinding process, the first surface 361 of the connector 36a may have a dished surface profile.

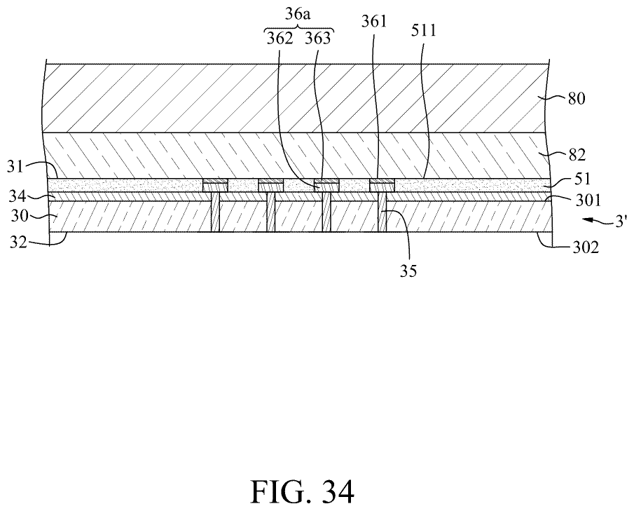

Referring to FIG. 34, a carrier 80 may be provided, and a release layer 82 may be formed or disposed on a surface of the carrier 80. The carrier 80 may be a glass substrate or a FR4 substrate. The carrier 80 may be in a panel type (or a panel structure) or a wafer type (or a wafer structure). Then, the first surface 361 of the connector 36a and the first surface 511 of the outermost dielectric layer 51 may be attached to or disposed on the release layer 82 on the carrier 80. Then, a grinding process may be conducted on the second surface 302 of the base main portion 30 so as to thin the base main portion 30 and expose the conductive via 35. Thus, the conductive via 35 may become a through via 35 extending through the base main portion 30.

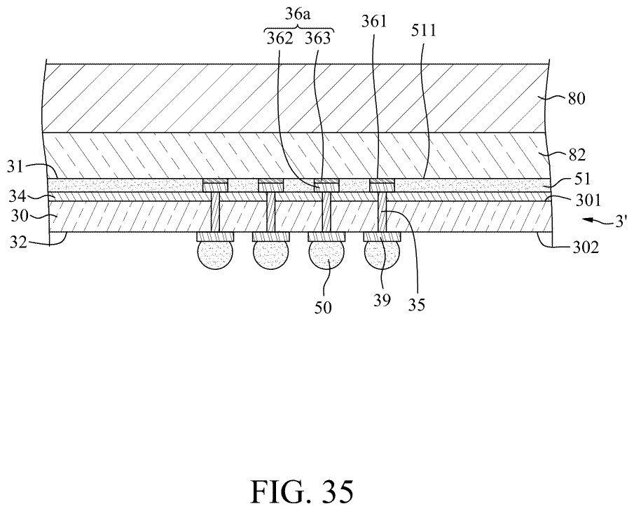

Referring to FIG. 35, a lower pad 39 may be formed on the second surface 302 of the base main portion 30 to contact the conductive via 35. The lower pad 39 may include Ni. Then, a solder material 50 may be formed on the lower pad 39. Meanwhile, the base electronic device 3′ may have a first surface 31 (e.g., a top surface, an upper surface, a first outer surface or a first outermost surface) and a second surface 32 (e.g., a lower surface, a bottom surface, a second outer surface or a second outermost surface) opposite to the first surface 31.

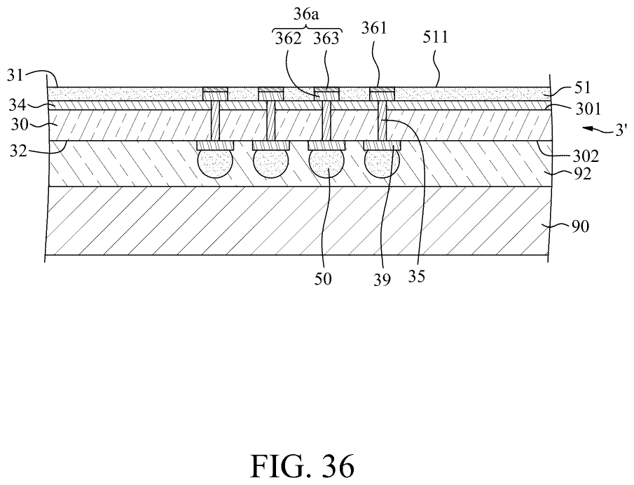

Referring to FIG. 36, a carrier 90 may be provided, and a release layer 92 may be formed or disposed on a surface of the carrier 90. The carrier 90 may be a glass substrate or a FR4 substrate. The carrier 90 may be in a panel type (or a panel structure) or a wafer type (or a wafer structure). Then, the second surface 32 of the base electronic device 3′ and the solder material 50 may be attached to or disposed on the release layer 92 on the carrier 90. Then, the release layer 82 and the carrier 80 may be removed.

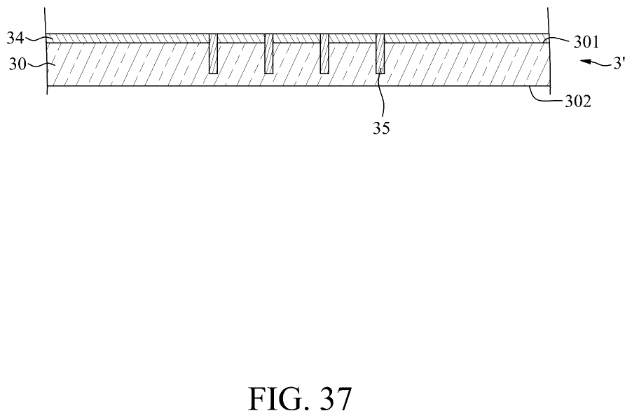

FIG. 37 through FIG. 42 illustrate a manufacturing method for manufacturing a base electronic device 3′ according to some embodiments of the present disclosure.

Referring to FIG. 37, a base electronic device 3′ may be provided. The base electronic device 3′ may be in a panel type (or a panel structure) or a wafer type (or a wafer structure). The base electronic device 3′ may be a logic device or a ASIC chip. The base electronic device 3′ may include a base main portion 30 and a conductive structure 34. The base main portion 30 may be a semiconductor substrate, and may include, for example, silicon (Si) or other semiconductor materials. The base main portion 30 may have a first surface 301 and a second surface 302 opposite to the first surface 301. The conductive structure 34 may be formed or disposed on the first surface 301 of the base main portion 30. The conductive structure 34 of FIG. 37 may be the same as the conductive structure 34 of FIG. 31. Then, a conductive via 35 may be formed to extend through the conductive structure 34 and extend into the base main portion 30.

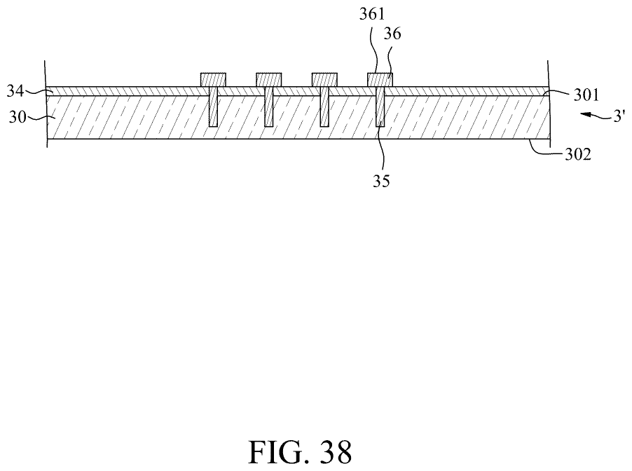

Referring to FIG. 38, at least one connector 36 (or at least one top connector, at least one pad, or at least one top pad) may be formed or disposed on the conductive structure 34. The connector 36 (or the pad) may include Cu. The connector 36 may be formed as follows. A seed layer may be formed on the conductive structure 34 by sputtering. A patterned photoresist layer may be formed on the seed layer. A metal material (e.g., Cu) may be formed in the opening of the patterned photoresist layer. The patterned photoresist layer may be removed by stripping. The seed layer that is not covered by the metal material (e.g., Cu) is removed by etching. Therefore, the connector 36 may be formed. The connector 36 (or the pad) may have a first surface 361 (e.g., an upper surface, a top surface, a first outer surface or a first outermost surface).

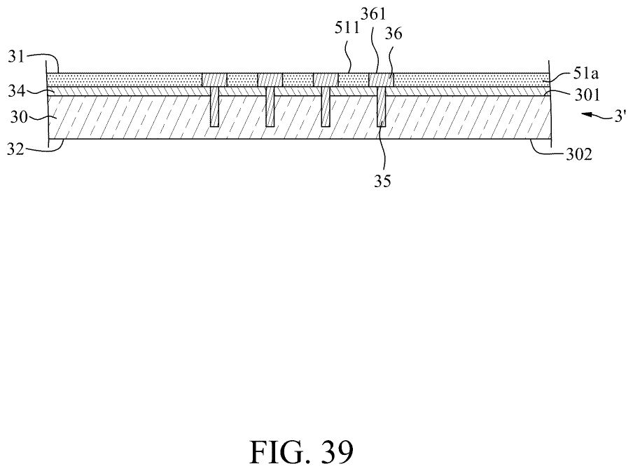

Referring to FIG. 39, an outermost dielectric layer 51a may be formed on the conductive structure 34 on the base main portion 30 by spin coating to cover and contact the connector 36. The outermost dielectric layer 51a may include an organic polymer material such as PI. Then, the outermost dielectric layer 51a may be pre-cured. The outermost dielectric layer 51a may have a first surface 511 (e.g., an upper surface, a top surface, a first outer surface or a first outermost surface). Then, a grinding process (e.g., a chemical mechanical polishing (CMP) process) may be conducted on the first surface 361 of the connector 36 and the first surface 511 of the outermost dielectric layer 51a. After the grinding process, the first surface 361 of the connector 36 may protrude from the first surface 511 of the outermost dielectric layer 51a.

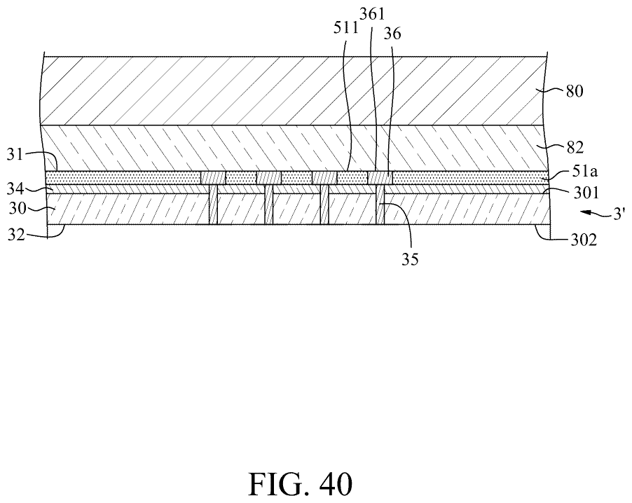

Referring to FIG. 40, a carrier 80 may be provided, and a release layer 82 may be formed or disposed on a surface of the carrier 80. The carrier 80 may be a glass substrate or a FR4 substrate. The carrier 80 may be in a panel type (or a panel structure) or a wafer type (or a wafer structure). Then, the first surface 361 of the connector 36 and the first surface 511 of the outermost dielectric layer 51a may be attached to or disposed on the release layer 82 on the carrier 80. Then, a grinding process may be conducted on the second surface 302 of the base main portion 30 so as to thin the base main portion 30 and expose the conductive via 35. Thus, the conductive via 35 may become a through via 35 extending through the base main portion 30.

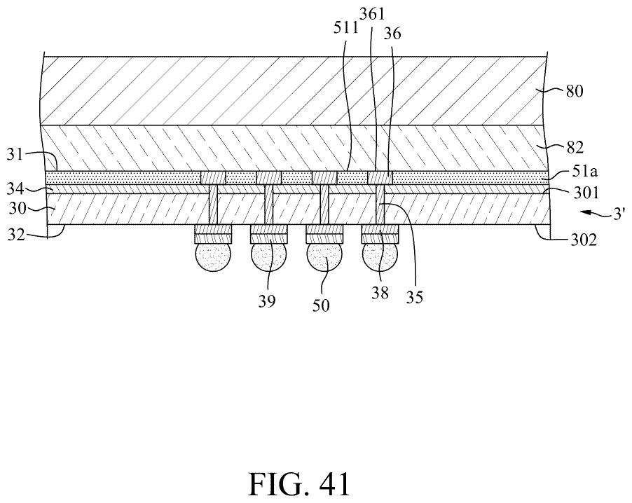

Referring to FIG. 41, a bottom pad 38 may be formed on the second surface of the base main portion 30 to contact the conductive via 35. The bottom pad 38 may include Cu. A lower pad 39 may be formed on the bottom pad 38. The lower pad 39 may include Ni. Then, a solder material 50 may be formed on the lower pad 39. Meanwhile, the base electronic device 3′ may have a first surface 31 (e.g., a top surface, an upper surface, a first outer surface or a first outermost surface) and a second surface 32 (e.g., a lower surface, a bottom surface, a second outer surface or a second outermost surface) opposite to the first surface 31.

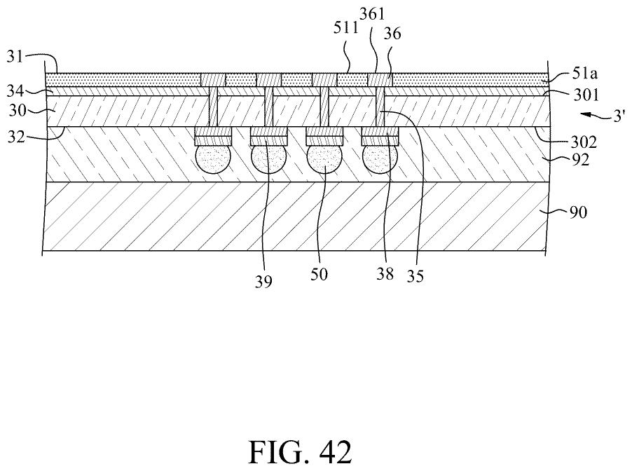

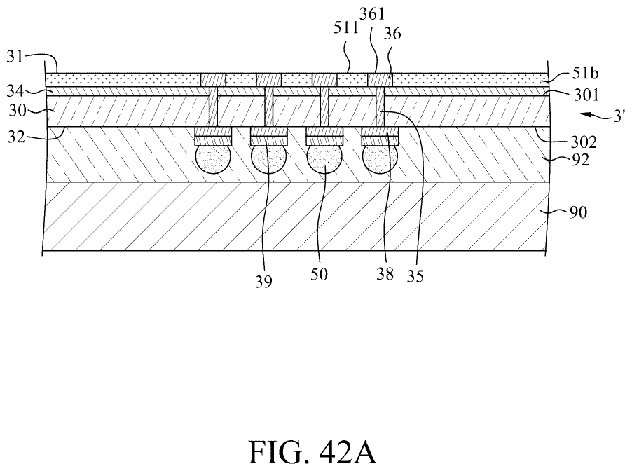

Referring to FIG. 42, a carrier 90 may be provided, and a release layer 92 may be formed or disposed on a surface of the carrier 90. The carrier 90 may be a glass substrate or a FR4 substrate. The carrier 90 may be in a panel type (or a panel structure) or a wafer type (or a wafer structure). Then, the second surface 32 of the base electronic device 3′ and the solder material 50 may be attached to or disposed on the release layer 92 on the carrier 90. Then, the release layer 82 and the carrier 80 may be removed.

FIG. 42A illustrates a cross-sectional view of a base electronic device 3′ according to some embodiments of the present disclosure. The base electronic device 3′ of FIG. 42A is similar to the base electronic device 3′of FIG. 42 except for the material of the outermost dielectric layer 51b. The material of the outermost dielectric layer 51b may include an inorganic material such as SiO₂, SiCN and/or SiN.

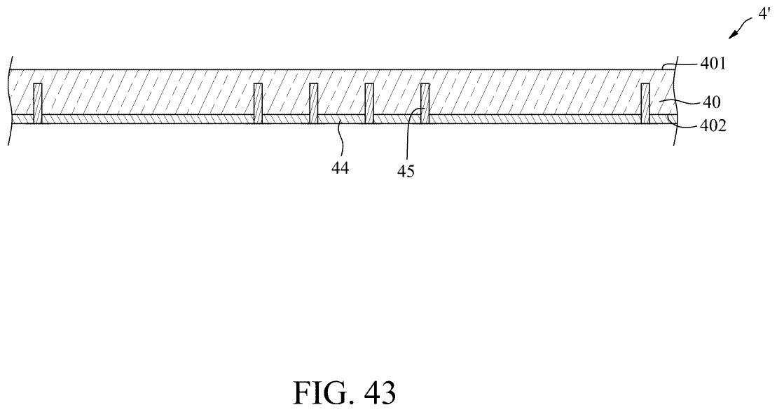

FIG. 43 through FIG. 48 illustrate a manufacturing method for manufacturing a middle electronic device 4 according to some embodiments of the present disclosure.

Referring to FIG. 43, a middle electronic device 4′ may be provided. The middle electronic device 4′ may be in a panel type (or a panel structure) or a wafer type (or a wafer structure). The middle electronic device 4′ may be or may include a semiconductor chip such as a memory chip. The middle electronic device 4′ may be or may include a dynamic random access memory (DRAM) chip. The middle electronic device 4′ may include a middle main portion 40 and a conductive structure 44. The middle main portion 40 may be a semiconductor substrate, and may include, for example, silicon (Si) or other semiconductor materials. The middle main portion 40 may have a first surface 401 and a second surface 402 opposite to the first surface 401. The conductive structure 44 may be formed or disposed on the second surface 402 of the middle main portion 40. The conductive structure 44 of FIG. 37 may be the same as the first conductive structure 114 of FIG. 1. Then, a conductive via 35 may be formed to extend through the conductive structure 44 and extend into the middle main portion 40.

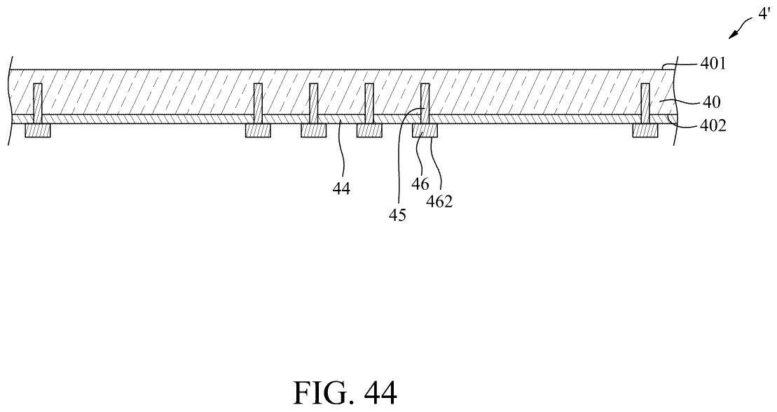

Referring to FIG. 44, at least one connector 46 (or at least one pad) may be formed or disposed on the conductive structure 44. The connector 46 (or the pad) may include Cu. The connector 46 may be formed as follows. A seed layer may be formed on the conductive structure 44 by sputtering. A patterned photoresist layer may be formed on the seed layer. A metal material (e.g., Cu) may be formed in the opening of the patterned photoresist layer. The patterned photoresist layer may be removed by stripping. The seed layer that is not covered by the metal material (e.g., Cu) is removed by etching. Therefore, the connector 46 may be formed. The connector 46 (or the pad) may have a second surface 462 (e.g., a lower surface, a bottom surface, a second outer surface or a second outermost surface).

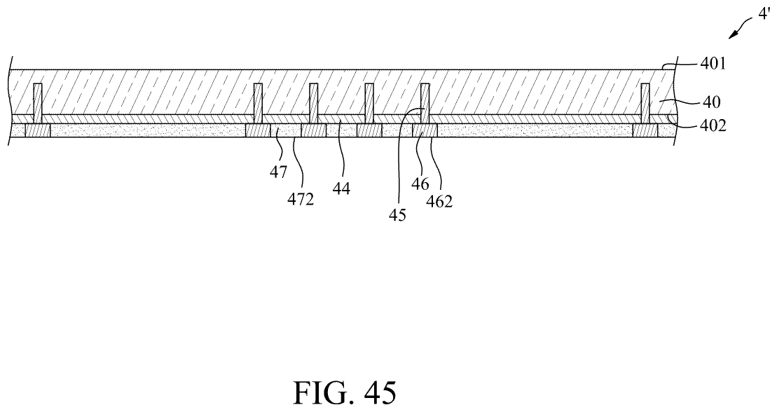

Referring to FIG. 45, an outermost dielectric layer 47 may be formed on the conductive structure 44 on the middle main portion 40 by spin coating to cover and contact the connector 46. The material of the outermost dielectric layer 47 may be the same as the material of the outermost dielectric layer 117 of FIG. 1. The outermost dielectric layer 47 may include an organic polymer material. The outermost dielectric layer 47 may include silicate. A surface energy of the outermost dielectric layer 47 may be greater than 2.5 J/m². Then, the outermost dielectric layer 47 may be pre-cured. The outermost dielectric layer 47 may have a second surface 472 (e.g., a lower surface, a bottom surface, a second outer surface or a second outermost surface). Then, a grinding process (e.g., a chemical mechanical polishing (CMP) process) may be conducted on the second surface 462 of the connector 46 and the second surface 472 of the outermost dielectric layer 47. After the grinding process, the second surface 462 of the connector 46 may have a dished surface profile.

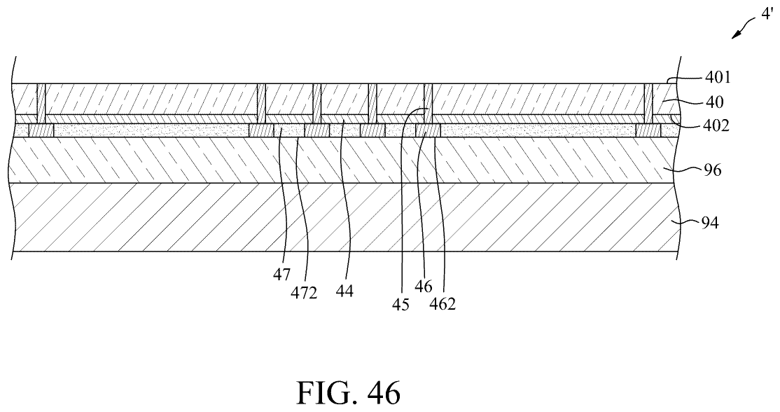

Referring to FIG. 46, a carrier 94 may be provided, and a release layer 96 may be formed or disposed on a surface of the carrier 94. The carrier 94 may be a glass substrate or a FR4 substrate. The carrier 94 may be in a panel type (or a panel structure) or a wafer type (or a wafer structure). Then, the second surface 462 of the connector 46 and the second surface 472 of the outermost dielectric layer 47 may be attached to or disposed on the release layer 96 on t he carrier 94. Then, a grinding process may be conducted on the first surface 401 of the middle main portion 40 so as to thin the middle main portion 40 and expose the conductive via 45. Thus, the conductive via 45 may become a through via 45 extending through the middle main portion 40.

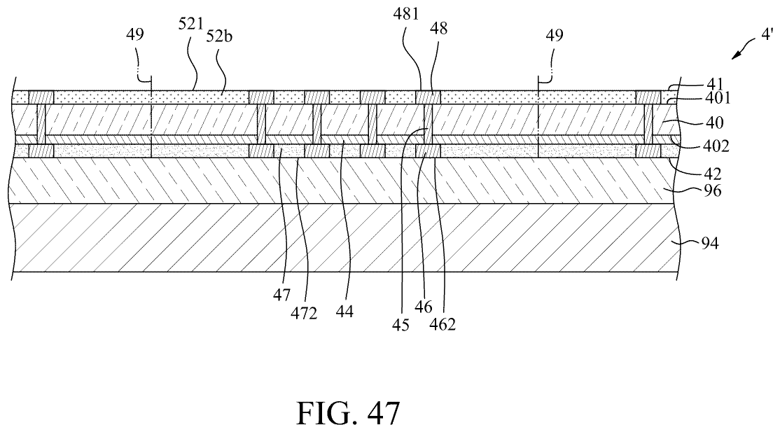

Referring to FIG. 47, a top pad 48 may be formed on the first surface 401 of the middle main portion 40 to contact the conductive via 45. The top pad 48 may include Cu. The top pad 48 may have a first surface 481 (e.g., a top surface, an upper surface, a first outer surface or a first outermost surface). Then, a top dielectric layer 52b may be formed on the first surface 401 of the middle main portion 40 by spin coating to cover and contact the top pad 48. The material of the top dielectric layer 52b may include an inorganic material such as SiO₂, SiCN and/or SiN. The top dielectric layer 52b may have a first surface 521 (e.g., an upper surface, a top surface, a first outer surface or a first outermost surface). Then, a grinding process (e.g., a chemical mechanical polishing (CMP) process) may be conducted on the first surface 481 of the top pad 48 and the first surface 521 of the top dielectric layer 52b.

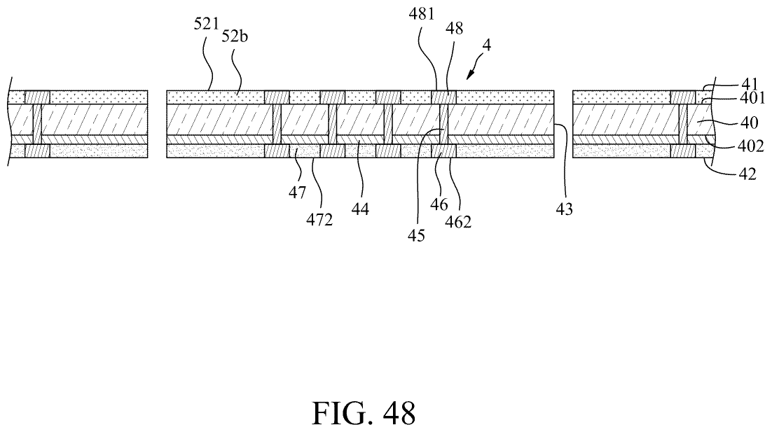

Referring to FIG. 48, a singulation process may be conducted along the cutting lines 49 so as to form a plurality of middle electronic devices 4. The middle electronic device 4 may have a first surface 41 (e.g., a top surface, an upper surface, a first outer surface or a first outermost surface), a second surface 42 (e.g., a lower surface, a bottom surface, a second outer surface or a second outermost surface) opposite to the first surface 41, and a lateral surface 43 extending between the first surface 41 and the second surface 42. The middle electronic device 4 may be also referred to as “a first electronic device”, “a second electronic device” or “a third electronic device”.

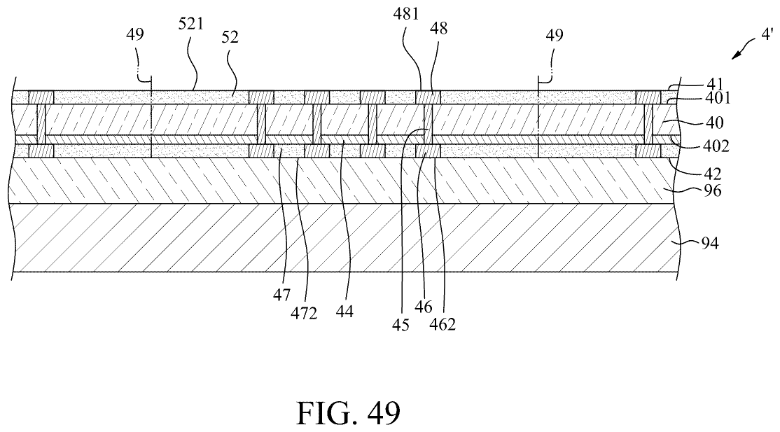

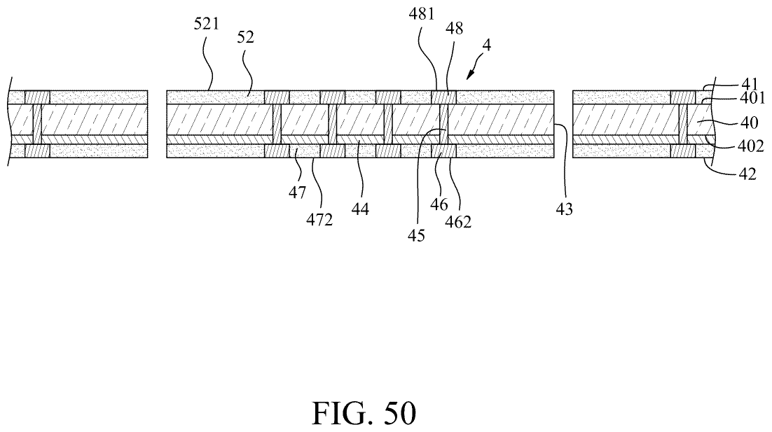

FIG. 49 through FIG. 50 illustrate a manufacturing method for manufacturing a middle electronic device 4 according to some embodiments of the present disclosure. The initial stages of the illustrated process are the same as, or similar to, the stages illustrated in FIG. 43 to FIG. 46. FIG. 49 depicts a stage subsequent to that depicted in FIG. 46.

Referring to FIG. 49, a top pad 48 may be formed on the first surface 401 of the middle main portion 40 to contact the conductive via 45. The top pad 48 may include Cu. The top pad 48 may have a first surface 481 (e.g., a top surface, an upper surface, a first outer surface or a first outermost surface). Then, a top dielectric layer 52 may be formed on the first surface 401 of the middle main portion 40 by spin coating to cover and contact the top pad 48. The top dielectric layer 52 may include an organic polymer material. The top dielectric layer 52 may include silicate. A surface energy of the top dielectric layer 52 may be greater than 2.5 J/m². Then, the top dielectric layer 52 may be pre-cured. The top dielectric layer 52 may have a first surface 521 (e.g., an upper surface, a top surface, a first outer surface or a first outermost surface). Then, a grinding process (e.g., a chemical mechanical polishing (CMP) process) may be conducted on the first surface 481 of the top pad 48 and the first surface 521 of the top dielectric layer 52.

Referring to FIG. 50, a singulation process may be conducted along the cutting lines 49 so as to form a plurality of middle electronic devices 4.

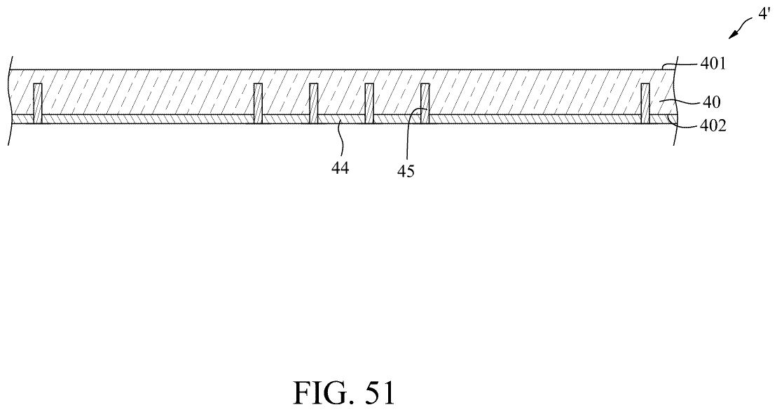

FIG. 51 through FIG. 56 illustrate a manufacturing method for manufacturing a middle electronic device 4 according to some embodiments of the present disclosure.

Referring to FIG. 51, a middle electronic device 4′ may be provided. The middle electronic device 4′ of FIG. 51 may be the same as the middle electronic device 4′ of FIG. 43.

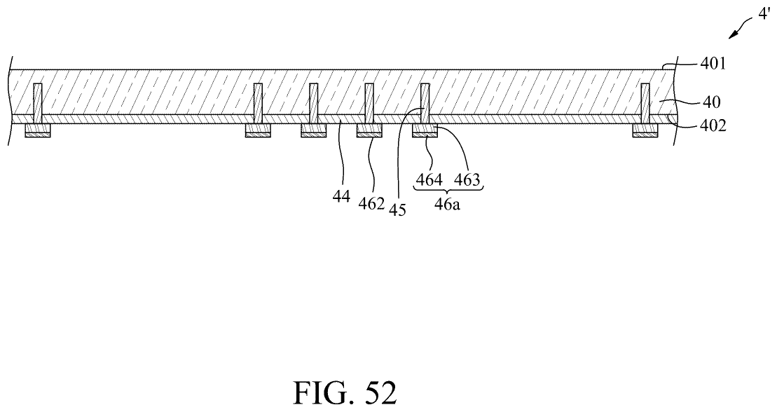

Referring to FIG. 52, at least one connector 46a (or at least one pad) may be formed or disposed on the conductive structure 44. The connector 46a (or the pad) may include a first layer 463 and a second layer 464 disposed on the first layer 463. The first layer 463 may include Ni. The second layer 464 may include Au. The connector 46a may be formed as follows. A seed layer may be formed on the conductive structure 44 by sputtering. A patterned photoresist layer may be formed on the seed layer. The first layer 463 (e.g., Ni) and the second layer 464 (e.g., Au) may be formed in the opening of the patterned photoresist layer. The patterned photoresist layer may be removed by stripping. The seed layer that is not covered by the first layer 463 (e.g., Ni) and the second layer 464 (e.g., Au) is removed by etching. Therefore, the connector 46a (including the first layer 463, the second layer 464 and the remaining seed layer) may be formed. The connector 46a (or the pad) may have a second surface 462 (e.g., a lower surface, a bottom surface, a second outer surface or a second outermost surface).

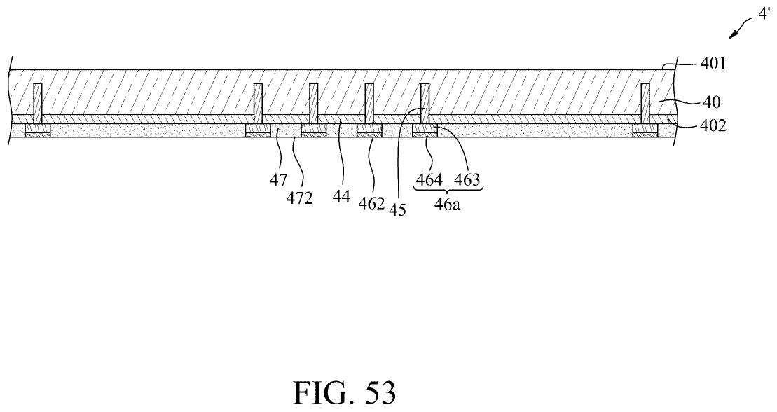

Referring to FIG. 53, an outermost dielectric layer 47 may be formed on the conductive structure 44 on the middle main portion 40 by spin coating to cover and contact the connector 46. The material of the outermost dielectric layer 47 may be the same as the material of the outermost dielectric layer 117 of FIG. 1. Then, the outermost dielectric layer 47 may be pre-cured. The outermost dielectric layer 47 may have a second surface 472 (e.g., a lower surface, a bottom surface, a second outer surface or a second outermost surface). Then, a grinding process (e.g., a chemical mechanical polishing (CMP) process) may be conducted on the second surface 462 of the connector 46 and the second surface 472 of the outermost dielectric layer 47. After the grinding process, the second surface 462 of the connector 46 may have a dished surface profile.

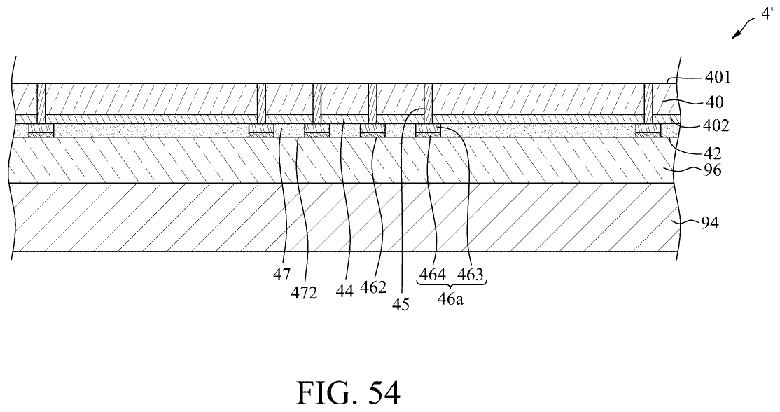

Referring to FIG. 54, a carrier 94 may be provided, and a release layer 96 may be formed or disposed on a surface of the carrier 94. Then, the second surface 462 of the connector 46 and the second surface 472 of the outermost dielectric layer 47 may be attached to or disposed on the release layer 96 on the carrier 94. Then, a grinding process may be conducted on the first surface 401 of the middle main portion 40 so as to thin the middle main portion 40 and expose the conductive via 45. Thus, the conductive via 45 may become a through via 45 extending through the middle main portion 40.

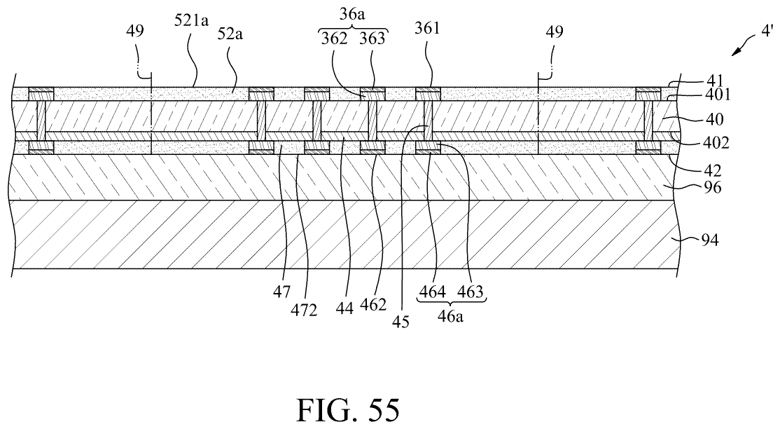

Referring to FIG. 55, a top connector 36a (or top pad) may be formed on the first surface 401 of the middle main portion 40 to contact the conductive via 45. The top connector 36a (or the top pad) may include a first layer 362 and a second layer 363 disposed on the first layer 362. The first layer 362 may include Ni. The second layer 363 may include Au. The top connector 36a (or the top pad) may have a first surface 361 (e.g., an upper surface, a top surface, a first outer surface or a first outermost surface).

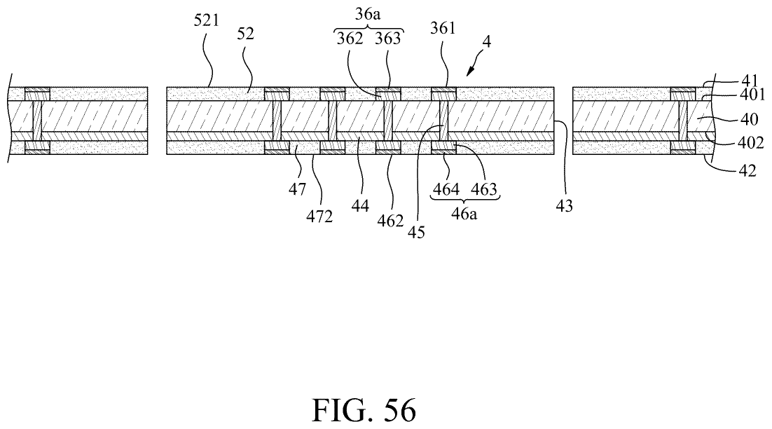

Referring to FIG. 56, a singulation process may be conducted along the cutting lines 49 so as to form a plurality of middle electronic devices 4.

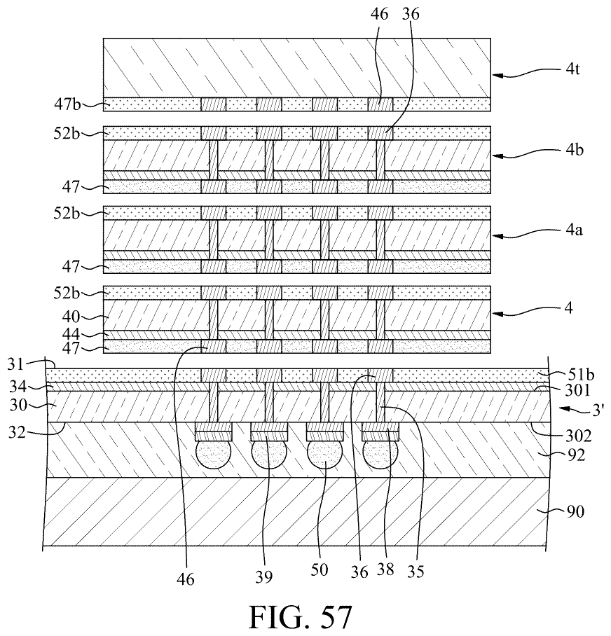

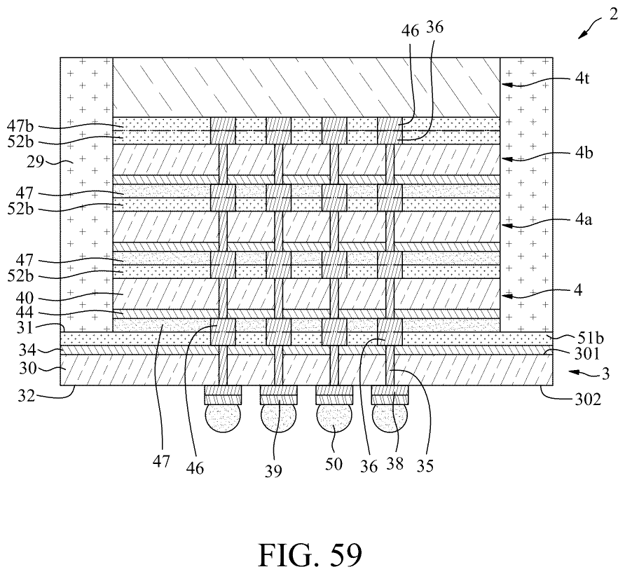

FIG. 57 through FIG. 59 illustrate a manufacturing method for manufacturing an assembly structure according to some embodiments of the present disclosure. In some embodiments, the method is for manufacturing the assembly structure 2 shown in FIG. 59.

Referring to FIG. 57, a base electronic device 3′, a first middle electronic device 4 a second middle electronic device 4a, a third middle electronic device 4b and a top electronic device 4t may be provided. The base electronic device 3′ of FIG. 57 may be the same as the base electronic device 3′ of FIG. 42A, and may be formed or disposed on a release layer 92 on a carrier 90. The first middle electronic device 4 of FIG. 57 may be the same as the middle electronic device 4 of FIG. 48, and may be stacked on or bonded to the base electronic device 3′. Thus, the outermost dielectric layer 47 of the first middle electronic device 4 may be adhered to or bonded to the outermost dielectric layer 51b of the base electronic device 3′. The second middle electronic device 4a of FIG. 57 may be the same as the middle electronic device 4 of FIG. 48, and may be stacked on or bonded to the first middle electronic device 4. Thus, the outermost dielectric layer 47 of the second middle electronic device 4a may be adhered to or bonded to the top dielectric layer 52b of the first middle electronic device 4. The third middle electronic device 4b of FIG. 57 may be the same as the middle electronic device 4 of FIG. 48, may be stacked on or bonded to the second middle electronic device 4a. Thus, the outermost dielectric layer 47 of the third middle electronic device 4b may be adhered to or bonded to the top dielectric layer 52b of the second middle electronic device 4a. The top electronic device 4t may be the same as the top electronic device 4t of FIG. 30B, and may be stacked on or bonded to the third middle electronic device 4b. Thus, the outermost dielectric layer 47b of the top electronic device 4t may be adhered to or bonded to the top dielectric layer 52b of the third middle electronic device 4b.

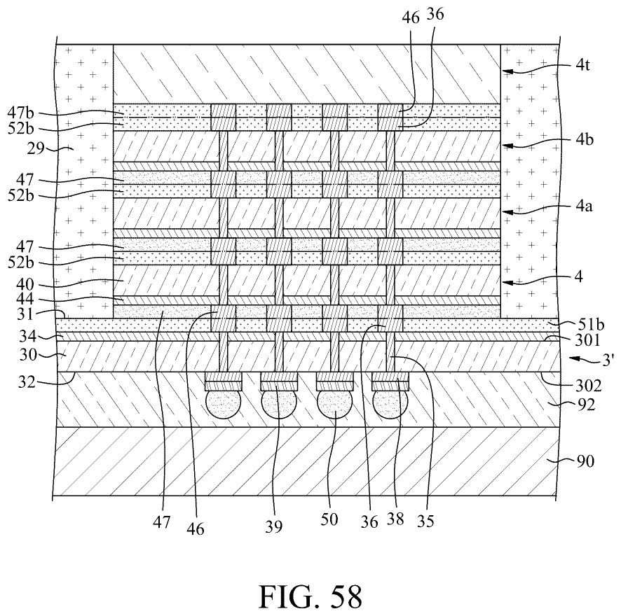

Referring to FIG. 58, an annealing process may be conducted. The connector 4 of the first middle electronic device 4 may be bonded to the connector 36 (or top connector 36) of the base electronic device 3′. There may be an interface between the connector 46 and the connector 36. Alternatively, the interface may not be obvious or visible. New metal grains may grow across the interface, and the connector 46 and the connector 36 may be merged into a single homogeneous metallic structure. The connector 46 of the second middle electronic device 4a may be bonded to the connector 36 (or top connector 36) of the first middle electronic device 4. The connector 46 of the third middle electronic device 4b may be bonded to the connector 36 (or top connector 36) of the second middle electronic device 4 a. The connector 46 of the top middle electronic device 4t may be bonded to the connector 36 (or top connector 36) of the third middle electronic device 4b.

Then, an encapsulant 29 may be formed on the first surface 31 (e.g., the top surface) of the base electronic device 3′to encapsulate the first middle electronic device 4, the second middle electronic device 4a, the third middle electronic device 4b and the top electronic device 4t.

Referring to FIG. 59, the release layer 92 and the carrier 90 may be removed. Then, a singulation process may be conducted so as to form a plurality of assembly structures 2. Meanwhile, the base electronic device 3′ may be singulated to become a base electronic device 3.

FIG. 59 illustrates a cross-sectional view of an assembly structure 2 according to some embodiments of the present disclosure. The assembly structure 2 may be an electronic package structure, a semiconductor package structure, an electronic structure, an electronic device or a semiconductor device. The assembly structure 2 may be also referred to as “a three-dimensional form factor device”. The assembly structure 2 may be a high bandwidth memory (HBM). The assembly structure 2 may include a base electronic device 3, a first electronic device 4 (e.g., a first middle electronic device 4), a second electronic device 4a (e.g., a second middle electronic device 4a), a third electronic device 4b (e.g., a third middle electronic device 4b) and a top electronic device 4t, an encapsulant 29 and a plurality of solder materials 50.

The base electronic device 3 may be a substrate, a semiconductor die, a semiconductor chip or an integrated circuit die. The base electronic device 3 may be also referred to as “a first electronic device” or “a second electronic device”. In some embodiments, the base electronic device 3 may be a logic device such as a logic die or a logic chip. In some embodiments, the base electronic device 3 may include an application-specific integrated circuit (ASIC) chip. The base electronic device 3 may be a controller chip such as an application processor (AP) chip. The base electronic device 3 may be disposed under the first electronic device 4, and may be electrically connected to the first electronic device 4. The base electronic device 3 (or the logic device or the ASIC chip) may have a first surface 31 (e.g., a top surface, an upper surface, a first outer surface or a first outermost surface), a second surface 32 (e.g., a lower surface, a bottom surface, a second outer surface or a second outermost surface) opposite to the first surface 31, and a lateral surface extending between the first surface 31 and the second surface 32. The base electronic device 3 (or the logic device or the ASIC chip) may include a base main portion 30, a conductive structure 34, a plurality of through vias 35, a plurality of top connectors 36, an outermost dielectric layer 51b, a plurality of bottom pads 38 and a plurality of lower pads 39. A width of the base electronic device 3 is greater than a width of the first electronic device 4 and a width of the second electronic device 4a. The base electronic device 3 may be similar to the base electronic device 3′ of FIG. 42A.

The base main portion 30 may be a semiconductor substrate, and may include, for example, silicon (Si) or other semiconductor materials. The base main portion 30 may have a first surface 301 (e.g., a top surface, an upper surface, a first outer surface or a first outermost surface) and a second surface 302 (e.g., a lower surface, a bottom surface, a second outer surface or a second outermost surface) opposite to the first surface 301.

The conductive structure 34 may be disposed on the first surface 301 of the base main portion 30. In some embodiments, the conductive structure 34 may include a plurality of front-end-of-line (FEOL) devices, such as resistors, capacitors, inductors, and/or transistors. In some embodiments, the conductive structure 34 may further include at least one back-end-of-line (BEOL) interconnect pattern, e.g., a plurality of patterned circuit layers, electrically connected to the front-end-of-line (FEOL) devices. The conductive structure 34 may include a dielectric structure, a plurality of circuit layers (including a plurality traces and a plurality of pads) embedded in the dielectric structure, and a plurality of inner vias. The dielectric structure may be a multi-layer film stack deposited on the base main portion 30. The inner vias may be disposed in the dielectric structure, and may connect the circuit layers. The dielectric structure of the conductive structure 34 may include inorganic material or organic material. In some embodiments, the conductive structure 34 may be or may include a single dielectric layer.

The through vias 35 may extend through the base main portion 30 and the conductive structure 34. The top connectors 36 (or connectors, or top connectors, or pads, or top pads) may be formed or disposed on the conductive structure 34. The top connectors 36 (or the pads) may include Cu. The top connectors 36 (or the pads) may contact the through vias 35. The outermost dielectric layer 51b may be disposed on the conductive structure 34 on the base main portion 30, and surround and contact the top connectors 36 (or the pads). The material of the outermost dielectric layer 51b may include an inorganic material such as SiO₂, SiCN and/or SiN. The bottom pad 38 may be disposed formed on the second surface 302 of the base main portion 30 to contact the through via 35. The bottom pad 38 may include Cu. The lower pad 39 may be disposed on the bottom pad 38. The lower pad 39 may include Ni. The solder material 50 may be disposed on the lower pad 39.

The first electronic device 4 may be disposed over and may be bonded to the base electronic device 3. The first electronic device 4 may be also referred to as “a second electronic device”. The first electronic device 4 may be or may include a dynamic random access memory (DRAM) chip. The first electronic device 4 may be the same as the middle electronic device 4 of FIG. 48.

The second electronic device 4a may be disposed over and may be bonded to the first electronic device 4 so as to electrically connected to the first electronic device 4. The second electronic device 4a may be also referred to as “a first electronic device” or a “third electronic device”. The second electronic device 4a may be or may include a dynamic random access memory (DRAM) chip. The second electronic device 4a may be the same as the middle electronic device 4 of FIG. 48.

The third electronic device 4b may be disposed over and may be bonded to the second electronic device 4a so as to electrically connected to the second electronic device 4a. The third electronic device 4b may be or may include a dynamic random access memory (DRAM) chip. The third electronic device 4b may be the same as the middle electronic device 4 of FIG. 48. The structures of the first electronic device 4, the second electronic device 4a and the third electronic device 4b may be the same.

The top electronic device 4t may be disposed over may be bonded to the third electronic device 4b so as to electrically connected to the third electronic device 4b. The top electronic device 4t may be the same as the top electronic device 4t of FIG. 30B. The encapsulant 29 may be a molding compound with or without fillers. The encapsulant 29 may be disposed on the first surface 31 (e.g., the top surface) of the base electronic device 3 to encapsulate the first electronic device 4, the second electronic device 4a, the third electronic device 4b and the top electronic device 4t.

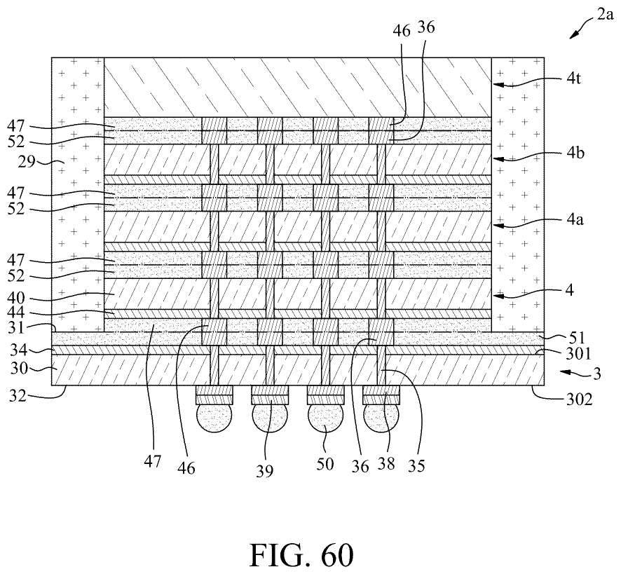

FIG. 60 illustrates a cross-sectional view of an assembly structure 2a according some embodiments of the present disclosure. The assembly structure 2a of FIG. 60 is similar to the assembly structure 2 of FIG. 59, and the differences are described as follows. In the assembly structure 2a, the base electronic device 3 may be similar to the base electronic device 3′ of FIG. 36 except that the top connector 36a of the base electronic device 3′ of FIG. 36 is replaced by the top connector 36 including Cu. In addition, a bottom pad 38 (including Cu) is disposed between the lower pad 39 and the base main portion 30. The first electronic device 4, the second electronic device 4a and the third electronic device 4b may be the same as the middle electronic device 4 of FIG. 50. The top electronic device 4t may be the same as the top electronic device 4t of FIG. 30A.

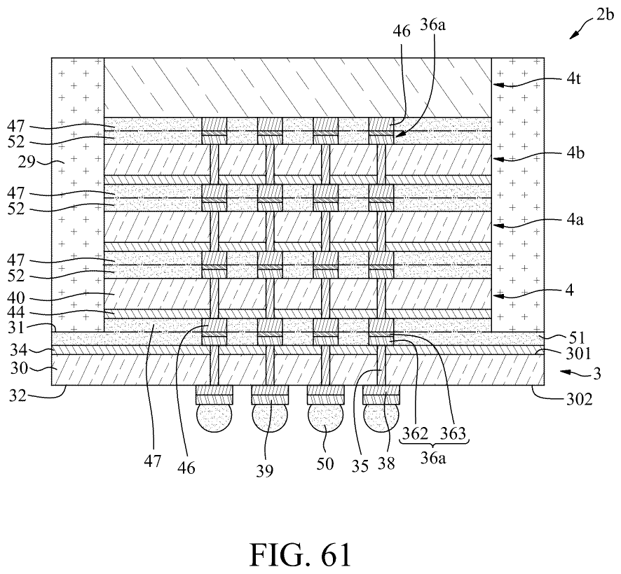

FIG. 61 illustrates a cross-sectional view of an assembly structure 2b according some embodiments of the present disclosure. The assembly structure 2b of FIG. 61 is similar to the assembly structure 2 of FIG. 59, and the differences are described as follows. In the assembly structure 2b, the base electronic device 3 may be similar to the base electronic device 3′ of FIG. 36 except that a bottom pad 38 (including Cu) is disposed between the lower pad 39 and the base main portion 30. The first electronic device 4, the second electronic device 4a and the third electronic device 4b may be similar to the middle electronic device 4 of FIG. 56 except that the connector 46a of the middle electronic device 4 of FIG. 56 is replaced by the connector 46 including Cu. The top electronic device 4t may be the same as the top electronic device 4t of FIG. 30A.

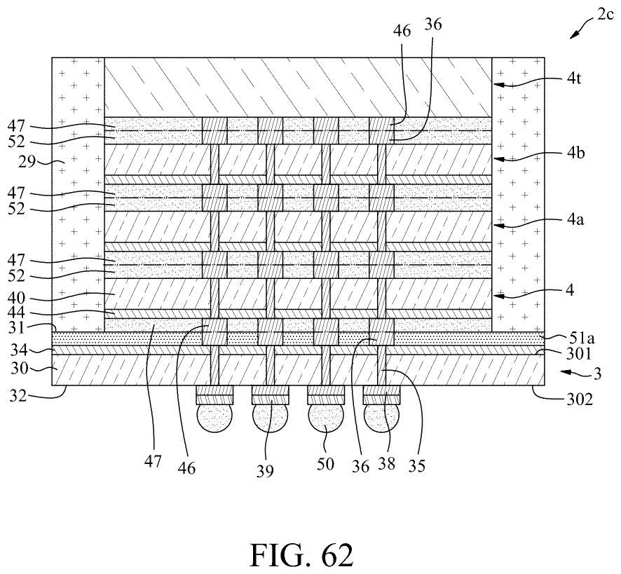

FIG. 62 illustrates a cross-sectional view of an assembly structure 2c according some embodiments of the present disclosure. The assembly structure 2c of FIG. 62 is similar to the assembly structure 2 of FIG. 59, and the differences are described as follows. In the assembly structure 2c, the base electronic device 3 may be similar to the base electronic device 3′ of FIG. 42. The first electronic device 4, the second electronic device 4a and the third electronic device 4b may be the same as the middle electronic device 4 of FIG. 50. The top electronic device 4t may be the same as the top electronic device 4t of FIG. 30A.

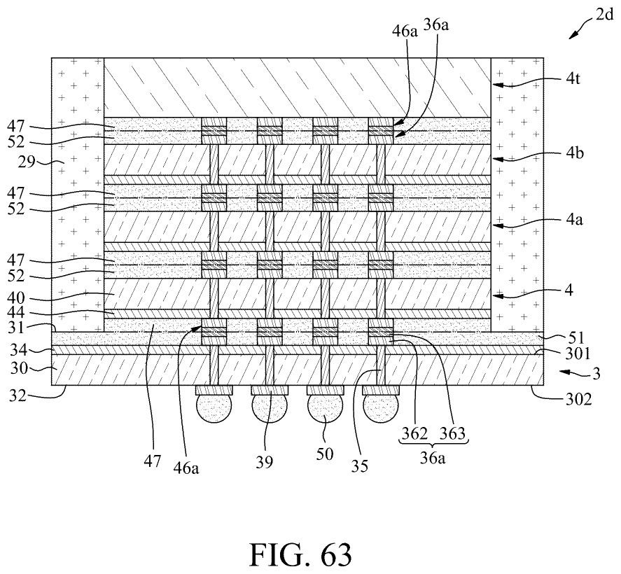

FIG. 63 illustrates a cross-sectional view of an assembly structure 2d according some embodiments of the present disclosure. The assembly structure 2d of FIG. 63 is similar to the assembly structure 2 of FIG. 59, and the differences are described as follows. In the assembly structure 2d, the base electronic device 3 may be similar to the base electronic device 3′ of FIG. 36. The first electronic device 4, the second electronic device 4a and the third electronic device 4b may be the same as the middle electronic device 4 of FIG. 56. The top electronic device 4t may be the same as the top electronic device 4t of FIG. 30A except that the connector 46 of the top electronic device 4t of FIG. 30A is replaced by the connector 46a including a first layer (e.g., Ni) and a second layer (e.g., Au).

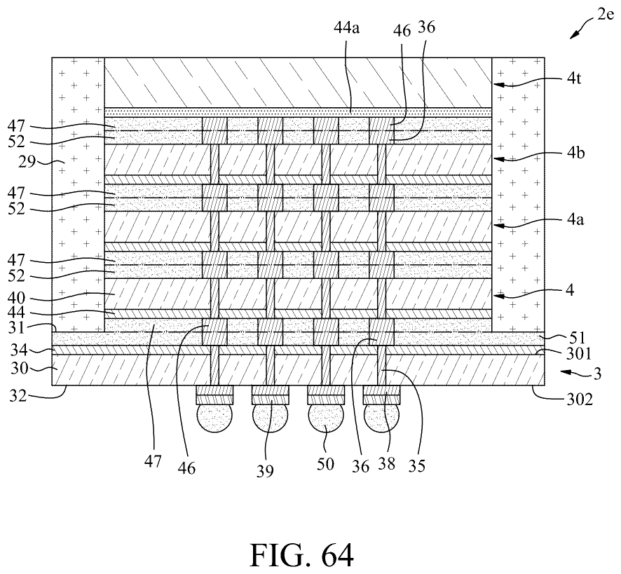

FIG. 64 illustrates a cross-sectional view of an assembly structure 2e according some embodiments of the present disclosure. The assembly structure 2e of FIG. 64 is similar to the assembly structure 2a of FIG. 60 except for the structure of the top electronic device 4t. The top electronic device 4t of FIG. 64 may be the same as the top electronic device 4t of FIG. 30.

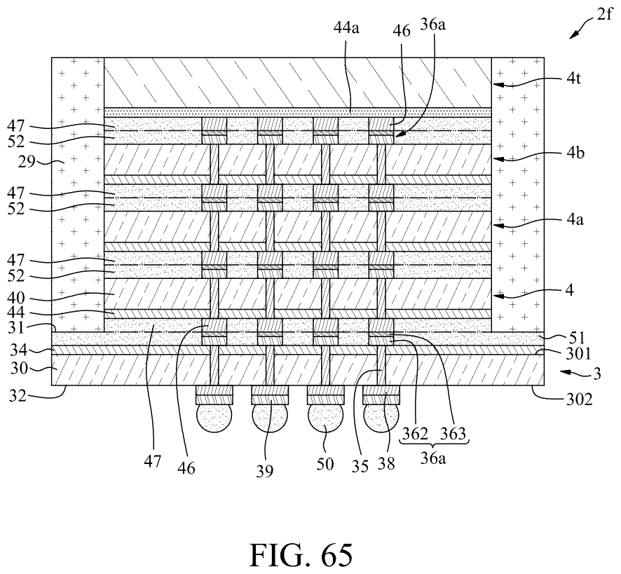

FIG. 65 illustrates a cross-sectional view of an assembly structure 2f according some embodiments of the present disclosure. The assembly structure 2f of FIG. 65 is similar to the assembly structure 2b of FIG. 61 except for the structure of the top electronic device 4t. The top electronic device 4t of FIG. 65 may be the same as the top electronic device 4t of FIG. 30.

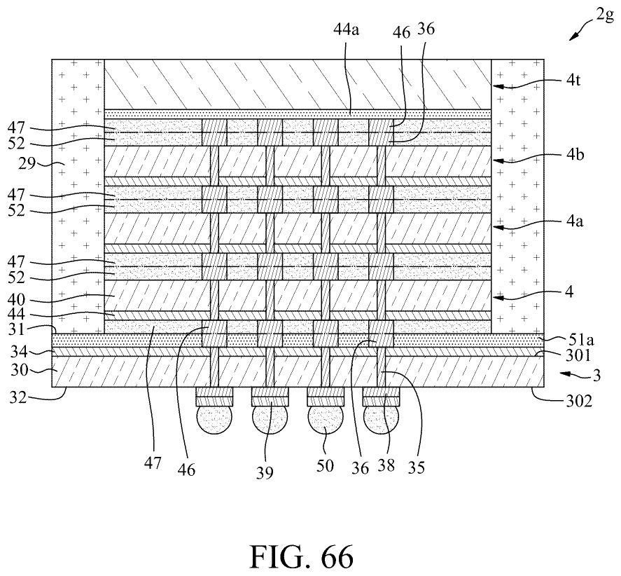

FIG. 66 illustrates a cross-sectional view of an assembly structure 2g according some embodiments of the present disclosure. The assembly structure 2g of FIG. 66 is similar to the assembly structure 2c of FIG. 62 except for the structure of the top electronic device 4t. The top electronic device 4t of FIG. 66 may be the same as the top electronic device 4t of FIG. 30.

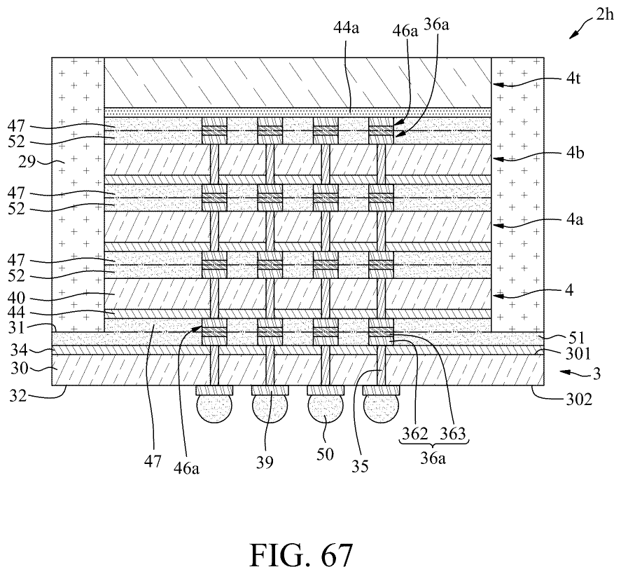

FIG. 67 illustrates a cross-sectional view of an assembly structure 2h according some embodiments of the present disclosure. The assembly structure 2h of FIG. 67 is similar to the assembly structure 2d of FIG. 63 except for the structure of the top electronic device 4t. The top electronic device 4t of FIG. 67 may further include a dielectric layer 44a.

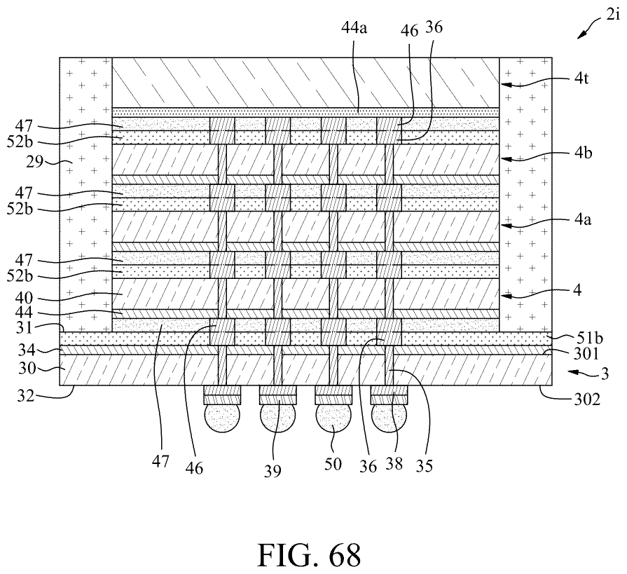

FIG. 68 illustrates a cross-sectional view of an assembly structure 2i according some embodiments of the present disclosure. The assembly structure 2i of FIG. 68 is similar to the assembly structure 2 of FIG. 59 except for the structure of the top electronic device 4t. The top electronic device 4t of FIG. 68 may be the same as the top electronic device 4t of FIG. 30.

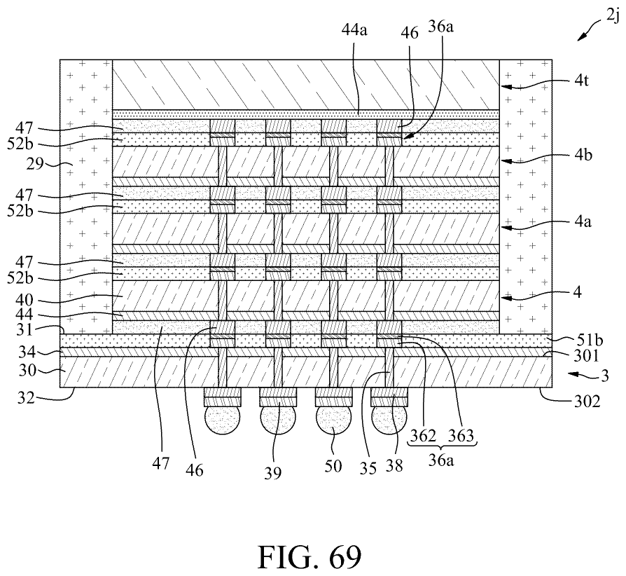

FIG. 69 illustrates a cross-sectional view of an assembly structure 2j according some embodiments of the present disclosure. The assembly structure 2j of FIG. 69 is similar to the assembly structure 2i of FIG. 68, and the differences are described as follows. In the assembly structure 2j, the base electronic device 3 of FIG. 69 may be similar to the base electronic device 3 of FIG. 68 except that the top connector 36 of the base electronic device 3 of FIG. 68 is replaced by the top connector 36a including a first layer (e.g., Ni) and a second layer (e.g., Au). The first electronic device 4, the second electronic device 4a and the third electronic device 4b of FIG. 69 may be similar to the first electronic device 4, the second electronic device 4a and the third electronic device 4b of FIG. 69 except that the top connector 36 of the first electronic device 4, the second electronic device 4a and the third electronic device 4b of FIG. 68 is replaced by the top connector 36a including a first layer (e.g., Ni) and a second layer (e.g., Au).

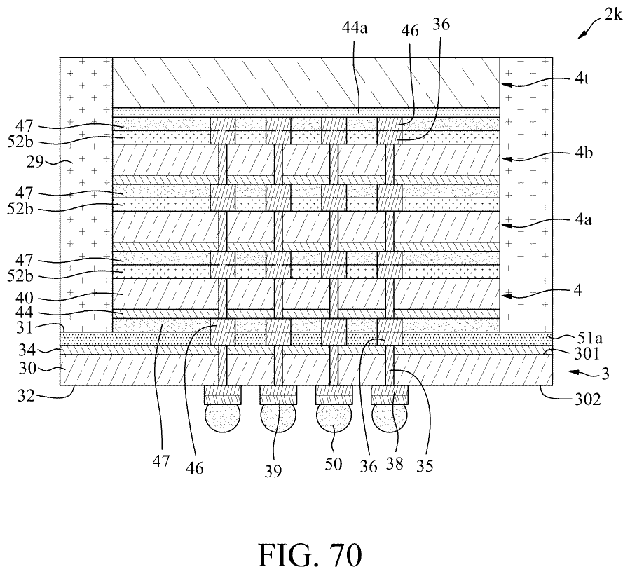

FIG. 70 illustrates a cross-sectional view of an assembly structure 2k according some embodiments of the present disclosure. The assembly structure 2k of FIG. 70 is similar to the assembly structure 2i of FIG. 68 except for the structure of the base electronic device 3. The base electronic device 3 of FIG. 70 may be similar to the base electronic device 3′ of FIG. 42.

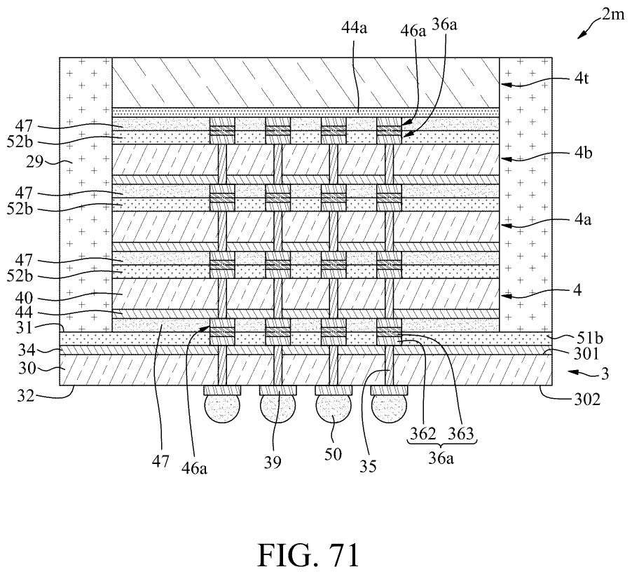

FIG. 71 illustrates a cross-sectional view of an assembly structure 2m according to some embodiments of the present disclosure. The assembly structure 2m of FIG. 71 is similar to the assembly structure 2h of FIG. 67, and the differences are described as follows. In the assembly structure 2m, the base electronic device 3 of FIG. 71 may be similar to the base electronic device 3 of FIG. 67 except that the outermost dielectric layer 51 of the base electronic device 3 of FIG. 67 is replaced by the outermost dielectric layer 51b including an inorganic material such as SiO₂, SiCN and/or SiN. In addition, the top dielectric layer 52 of the first electronic device 4, the second electronic device 4a and the third electronic device 4b of FIG. 67 is replaced by the top dielectric layer 52b including an inorganic material such as SiO₂, SiCN and/or SiN.

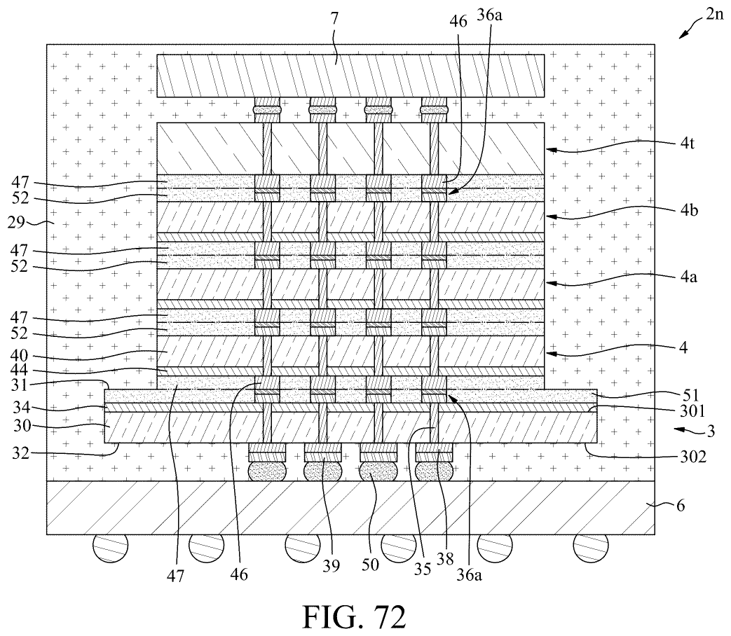

FIG. 72 illustrates a cross-sectional view of an assembly structure 2n according some embodiments of the present disclosure. The assembly structure 2n of FIG. 72 may include a base substrate 6, a base electronic device 3, a first electronic device 4, a second electronic device 4a, a third electronic device 4b, a top electronic device 4t, a plurality of solder materials 50, an additional top electronic device 7 and an encapsulant 29. The base substrate 6 may be a patterned circuit structure. The base substrate 6 may be an organic substrate including a cured resin and a plurality glass fibers disposed therein. For example, the base substrate 6 may be a FR4 substrate. The base electronic device 3, the first electronic device 4, the second electronic device 4a, the third electronic device 4b, the top electronic device 4t and the solder materials 50 of FIG. 72 may be the same as the base electronic device 3, the first electronic device 4, the second electronic device 4a, the third electronic device 4b, the top electronic device 4t and the solder materials 50 of FIG. 59. The base electronic device 3 may be electrically connected to the base substrate 6 through the solder materials 50. The first electronic device 4, the second electronic device 4a, the third electronic device 4b and the top electronic device 4t may be bonded to one another, and may be stacked on the base electronic device 3. The additional top electronic device 7 may be a semiconductor chip such as an application-specific integrated circuit (ASIC) chip or a graphics processing unit (GPU), and may be electrically connected to the top electronic device 4t. The encapsulant 29 may be disposed on the top surface of the base substrate 6 to encapsulate the base electronic device 3, the first electronic device 4, the second electronic device 4a, the third electronic device 4b, the top electronic device 4t, the solder materials 50 and the additional top electronic device 7. In addition, a plurality of external connectors (e.g., the solder balls) may be disposed on the bottom surface of the base substrate 6.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A manufacturing method, comprising:
forming a first dielectric layer and a first connector on a first main portion of a first electronic device, wherein the first dielectric layer includes an organic polymer material, the first dielectric layer includes silicate, wherein a surface energy of the first dielectric layer is greater than 2.5 J/m², wherein the first connector is exposed by the first dielectric layer;
forming a second dielectric layer and a second connector on a second main portion of a second electronic device, wherein the second dielectric layer includes an organic polymer material, wherein the second connector is exposed by the second dielectric layer;
bonding the first dielectric layer of the first electronic device to the second dielectric layer of the second electronic device at a room temperature;
fully curing the first dielectric layer; and
bonding the first connector and the second connector.

2. The manufacturing method of claim 1, wherein forming the first dielectric layer and the first connector on the first main portion of the first electronic device includes:
forming the first connector on the first main portion of the first electronic device;
coating the first dielectric layer on the first main portion of the first electronic device to contact the first connector; and
pre-curing the first dielectric layer.

3. The manufacturing method of claim 1, wherein forming the first dielectric layer and the first connector on the first main portion of the first electronic device includes:
coating the first dielectric layer on the first main portion of the first electronic device;
pre-curing the first dielectric layer;
forming a through hole extending through the first dielectric layer by laser drilling; and
forming the first connector in the through hole of the first dielectric layer on the first main portion of the first electronic device.

4. The manufacturing method of claim 1, further comprising:
grinding the first dielectric layer and the first connector, wherein the first connector is recessed from an outermost surface of the first electronic device; and
grinding the second dielectric layer and the second connector, wherein the second connector protrudes from an outermost surface of the second electronic device.

5. The manufacturing method of claim 1, wherein the first dielectric layer is a non-photosensitive material, wherein after fully curing the first dielectric layer, the first dielectric layer shrinks, the first dielectric layer has a glass transition temperature (Tg) greater than 400° C., and the first dielectric layer has a Young's modulus ranging from about 4.0 GPa to about 6.0 GPa.

6. The manufacturing method of claim 1, further comprising:
bonding the first electronic device to a base electronic device, wherein a width of the base electronic device is greater than a width of the first electronic device;
bonding a third electronic device to the second electronic device, wherein the third electronic device includes a third dielectric layer and a third connector on a third main portion of the electronic device, wherein a material of the third dielectric layer is the same as a material of the first dielectric layer; and
forming an encapsulant on a top surface of the base electronic device to encapsulate the first electronic device, the second electronic device and the third electronic device.

7. An assembly structure, comprising:
a first electronic device including:
a first main portion;
a first connector disposed on the first main portion; and
a first dielectric layer disposed on the first main portion and surrounding the first connector, wherein the first dielectric layer includes an organic polymer material, the first dielectric layer includes silicate, wherein a surface energy of the first dielectric layer is greater than 1.0 J/m²; and
a second electronic device including:
a second main portion;
a second connector disposed on the second main portion; and
a second dielectric layer disposed on the second main portion and surrounding the second connector, wherein the second dielectric layer includes an organic polymer material, wherein the first dielectric layer of the first electronic device is bonded to the second dielectric layer of the second electronic device, wherein the first connector is bonded to the second connector.

8. The assembly structure of claim 7, wherein the surface energy of the first dielectric layer is greater than 2.5 J/m², wherein the first dielectric layer has a glass transition temperature (Tg) greater than 400° C., wherein the first dielectric layer has a Young's modulus ranging from about 4.0 GPa to about 6.0 GPa.

9. The assembly structure of claim 7, wherein a material of the second dielectric layer is the same as a material of the first dielectric layer, wherein the first dielectric layer and the second dielectric layer collectively form a monolithic dielectric structure without an interface therebetween.

10. The assembly structure of claim 7, wherein a material of the second dielectric layer is different from a material of the first dielectric layer, wherein the second dielectric layer has a Young's modulus less than the Young's modulus of the first dielectric layer.

11. The assembly structure of claim 7, wherein the second main portion is a substrate including a cured resin and a plurality glass fibers disposed therein, wherein a material of the second dielectric layer includes a solder mask, a bismaleimide triazine (BT) or a Ajinomoto build-up film (ABF).

12. The assembly structure of claim 7, wherein the first main portion includes silicon, the first electronic device further includes a conductive structure disposed between the first main portion and the first dielectric layer, wherein the conductive structure includes at least one inner dielectric layer, wherein a material of the inner dielectric layer is different from a material of the first dielectric layer, wherein the inner dielectric layer has a Young's modulus less than the Young's modulus of the first dielectric layer, wherein the inner dielectric layer includes a photosensitive material.

13. The assembly structure of claim 7, wherein the first dielectric layer directly contacts a surface of the first main portion, wherein the first main portion includes a plurality of inner dielectric layers and plurality of circuit layers in contact with the plurality of inner dielectric layers, wherein a material of the plurality of inner dielectric layers is different from a material of the first dielectric layer, wherein the inner dielectric layer includes a photosensitive material.

14. The assembly structure of claim 8, further comprising:
a base electronic device disposed under and bonded to the first electronic device;
a third electronic device bonded to the second electronic device; and
an encapsulant disposed on a top surface of the base electronic device, and encapsulating the first electronic device, the second electronic device and the third electronic device.

15. An electronic device, comprising:
a main portion;
a conductive structure disposed on the main portion, and including:
a plurality of inner dielectric layers stacked on one another; and
a plurality of circuit layers in contact with the plurality of inner dielectric layers;
a pad disposed on and electrically connected to the conductive structure; and
an outermost dielectric layer disposed on the conductive structure and surrounding the pad, a material of the plurality of inner dielectric layers is different from a material of the outermost dielectric layer, wherein the outermost dielectric layer includes an organic and non-photosensitive material, the outermost dielectric layer includes silicate, wherein a surface energy of the first dielectric layer is greater than 2.5 J/m².

16. The electronic device of claim 15, wherein a surface roughness of a top surface of the outermost dielectric layer is less than a surface roughness of a top surface of the conductive structure.

17. The electronic device of claim 16, wherein the outermost dielectric layer has a glass transition temperature (Tg) greater than 400° C., wherein the outermost dielectric layer has a Young's modulus ranging from about 4.0 GPa to about 6.0 GPa, wherein the material of the plurality of inner dielectric layers includes a photosensitive material, wherein the inner dielectric layer has a Young's modulus less than the Young's modulus of the outermost dielectric layer.

18. The electronic device of claim 15, wherein the outermost dielectric layer defines a through hole for accommodating the pad, wherein a sidewall of the through hole includes an upper portion and a lower portion, wherein a surface roughness of the upper portion of the sidewall of the through hole is greater than a surface roughness of the lower portion of the sidewall of the through hole.

19. The electronic device of claim 18, wherein one of the plurality of inner dielectric layer defines an opening for accommodating an inner via for electrically connecting the plurality of circuit layers, wherein a surface roughness of a sidewall of the opening is less than a surface roughness of the lower portion of the sidewall of the through hole.

20. The electronic device of claim 19, wherein a top surface of the outermost dielectric layer includes a first portion adjacent to the through hole and a second portion away from the through hole, wherein a surface roughness of the first portion is greater than a surface roughness of the second portion.
